(19) United States
(12) Patent Application Publication
(10) Pub. No.: US 2019/0172960 A1
(43) Pub. Date: Jun. 6, 2019

(54) SOLAR CELLS AND METHODS OF MAKING SOLAR CELLS

(71) Applicant: King Abdullah University of Science and Technology, Thuwal (SA)

(72) Inventors: Jr-Hau HE, Thuwal (SA); Meng-Lin TSAI, Thuwal (SA)

(21) Appl. No.: 16/322,300

(22) PCT Filed: Aug. 1, 2017
(86) PCT No.: PCT/IB2017/054710

§ 371 Date: Jan. 31, 2019

Related U.S. Application Data
(60) Provisional application No. 62/369,566, filed on Aug. 1, 2016.

(51) Int. Cl. H01L 31/0336; H01L 31/032; H01L 31/0392; H01L 31/0224; H01L 31/0445; H01L 31/18; C30B 25/02; C30B 29/46; C30B 29/68; G01N 27/414

(52) U.S. Cl. CPC H01L 31/0336; H01L 31/032; H01L 31/0392; H01L 31/022425; G01N 27/4141; H01L 31/1896; C30B 25/02; C30B 29/46; C30B 29/68; H01L 31/0445

(57) ABSTRACT

Embodiments of the present disclosure describe a solar cell comprising a first monolayer and a second monolayer, the first monolayer and the second monolayer forming a monolayer p-n lateral heterojunction with an atomically sharp interface; and a substrate, the substrate and the monolayer p-n lateral heterojunction forming a solar cell. Embodiments of the present disclosure further describe a method of making a solar cell comprising growing a first monolayer on a first substrate; growing a second monolayer on the first substrate sufficient to form a monolayer p-n lateral heterojunction with an atomically sharp interface; and transferring the monolayer p-n lateral heterojunction from the first substrate to a second substrate sufficient to form a solar cell.

### BACKGROUND

Current methods of fabricating ultrathin electronic devices, such as diodes, photodetectors, and solar cells, limit the development of devices with vertically-stacked van der Waals 2D monolayer-based materials, which require a high degree of compositional and structural complexity. These methods include 2D monolayer-based material growth and multiple transfer techniques. Direct epitaxial growth of two types of 2D monolayer-based materials to form a 2D monolayer lateral heterojunction have been limited to certain metals and chalcogels, resulting in alloy structures at the interface that inhibit the formation of ideal p-n heterojunctions. Multiple transfer techniques further require complicated transferring steps and quenching centers at the interface/junction that introduce undesirable contaminants and defects. For these reasons, current methods limit both quality control and the development of processes for mass production of vertically-stacked van der Waals 2D monolayer-based devices.

The performance of 2D material field-effect transistors, photodiodes, and photovoltaic devices can be improved, given the gate-tuning properties of such devices. In some instances, improvements include high external quantum efficiency and fast photoresponse, as well as lower power consumption due to a reduction in the switching voltage to values lower than conventional metal oxide semiconductor field-effect transistors, for example. However, efficient gate control of van der Waals heterojunction-based devices require dual-gate design on both the top and bottom sides of the device. This requirement of dual-gate design not only increases fabrication time, but also cost and complexity.

The large surface area available for chemical gas adsorption, doping, and oxidation suggests 2D monolayer-based materials can operate as gas sensors. For instance, 2D monolayer-based materials as field-effect transistors are highly sensitive to environmental gases. Even as gas sensors, however, vertically-stacked van der Waals 2D monolayer-based devices are difficult to analyze because gas molecules can be adsorbed on the top and bottom monolayers. In non-gas sensor applications, the large surface area otherwise inhibits the operation of 2D monolayer-based devices. For this reason, additional protective layers such as PMMA are typically coated on top of 2D monolayer-based devices to increase stability and manage performance degradation by chemical gases. However, these protective layers increase overall device thickness and reduce the available light for absorption by the 2D monolayer-based material, degrading device performance and sensitivity.

### SUMMARY

In general, embodiments of the present disclosure describe solar cells and methods of making solar cells.

Accordingly, embodiments of the present disclosure describe a solar cell comprising a first monolayer and a second monolayer, the first monolayer and the second monolayer forming a monolayer p-n lateral heterojunction with an atomically sharp interface; and a substrate, the substrate and the monolayer p-n lateral heterojunction forming a solar cell.

Embodiments of the present disclosure further describe a method of making a solar cell comprising growing a first monolayer on a first substrate; growing a second monolayer on the first substrate sufficient to form a monolayer p-n lateral heterojunction with an atomically sharp interface; and transferring the monolayer p-n lateral heterojunction from the first substrate to a second substrate sufficient to form a solar cell.

### BRIEF DESCRIPTION OF DRAWINGS

This written disclosure describes illustrative embodiments that are non-limiting and non-exhaustive. In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

Reference is made to illustrative embodiments that are depicted in the figures, in which:

FIG. 1 illustrates a block flow diagram of a method of making a solar cell, according to one or more embodiments of the present disclosure.

FIG. 2a illustrates a high resolution STEM image of monolayer WSe₂—MoS₂ lateral heterostructures, according to one or more embodiments of the present disclosure.

FIG. 2b illustrates an AFM image of monolayer WSe₂—MoS₂ lateral heterostructures (scale bar, 1 nm), according to one or more embodiments of the present disclosure.

FIG. 2c illustrates a monolayer WSe₂—MoS₂ lateral heterostructures (scale bar, 1 μm, according to one or more embodiments of the present disclosure.

FIG. 2d illustrates a graphical view of Raman spectroscopy of MoS₂ and WSe₂ regions, according to one or more embodiments of the present disclosure.

FIG. 2e illustrates a graphical view of photoluminescence of MoS₂ and WSe₂ regions, according to one or more embodiments of the present disclosure.

FIG. 3a illustrates a schematic view and SEM image of monolayer WSe₂—MoS₂ lateral heterojunction photovoltaic devices connected in parallel (scale bar, 50 μm), according to one or more embodiments of the present disclosure.

FIG. 3b illustrates a graphical view of I-V characteristics of monolayer WSe₂—MoS₂ lateral heterojunction photovoltaic devices connected in parallel under AM 1.5G light illumination, according to one or more embodiments of the present disclosure.

FIG. 3c illustrates a graphical view of light intensity dependent FF of monolayer WSe₂—MoS₂ lateral heterojunction photovoltaic devices connected in parallel under AM 1.5G light illumination, according to one or more embodiments of the present disclosure.

FIG. 3d illustrates a graphical view of power conversion efficiency of monolayer WSe₂—MoS₂ lateral heterojunction photovoltaic devices connected in parallel under AM 1.5G light illumination, according to one or more embodiments of the present disclosure.

FIG. 3e illustrates a graphical view of angular dependent power conversion efficiency of monolayer WSe₂—MoS₂ lateral heterojunction photovoltaic devices connected in parallel under AM 1.5G light illumination, according to one or more embodiments of the present disclosure.

FIG. 4a is a schematic view of electrode spacing of monolayer WSe₂—MoS₂ lateral heterojunction, according to one or more embodiments of the present disclosure.

FIG. 4b illustrates a graphical view of simulated (lines) and experimental (symbols) dark I_{ds}-V_{g} characteristics of monolayer WSe₂—MoS₂ lateral heterojunctions at V_{ds} of 2 V with different electrode spacing distances, according to one or more embodiments of the present disclosure.

FIG. 4c illustrates a graphical view of dark I-V characteristics under various ambient conditions (vacuum, air, and O₂-rich) for monolayer WSe₂—MoS₂ lateral heterojunctions with 2 μm electrode spacing distances, according to one or more embodiments of the present disclosure.

FIG. 4d illustrates a graphical view of dark I-V characteristics under various ambient conditions (vacuum, air, and O₂-rich) for monolayer WSe₂—MoS₂ lateral heterojunctions with 5 μm electrode spacing distances, according to one or more embodiments of the present disclosure.

FIG. 4e is a graphical view of power conversion efficiency of a monolayer WSe₂—MoS₂ lateral heterojunction in various ambient environments, according to one or more embodiments of the present disclosure.

FIG. 5a is a graphical view of temperature dependent electrical characteristics of monolayer WSe₂—MoS₂ lateral heterojunctions in the dark, according to one or more embodiments of the present disclosure.

FIG. 5b is a graphical view of temperature dependent electrical characteristics of monolayer WSe₂—MoS₂ lateral heterojunctions under AM 1.5G illumination, according to one or more embodiments of the present disclosure.

FIG. 6 is a schematic view of a simulated monolayer WSe₂—MoS₂ lateral heterojunction, according to one or more embodiments of the present disclosure.

FIG. 7A is a schematic diagram of the sequential growth of the monolayer WSe₂—MoS₂ in-plane heterostructure, according to one or more embodiments of the present disclosure.

FIG. 7B is an optical image of WSe₂ and MoS₂ indicating that they can be distinguished by their optical contrast, according to one or more embodiments of the present disclosure.

FIG. 7C is a high-resolution STEM image taken from the WSe₂—MoS₂ in-plane heterostructure, according to one or more embodiments of the present disclosure.

FIG. 7D is a high-resolution STEM image taken from the WSe₂—MoS₂ in-plane heterostructure, according to one or more embodiments of the present disclosure.

FIG. 7E is a schematic view of an atomic model showing the interface structure between WSe₂ and MoS₂, according to one or more embodiments of the present disclosure.

FIG. 8A illustrates intensity maps of the perpendicular Iᵥ and parallel I_{H} components of the SH, with the insert showing the optical image and the black double arrow line indicating the direction of incident laser polarization (scale bar is 5 μm), according to one or more embodiments of the present disclosure.

FIG. 8B illustrates intensity maps of the Iᵥ and I_{H} components of the SH for a multidomain WSe₂—MoS₂ junction (scale bar is 5 μm), according to one or more embodiments of the present disclosure.

FIG. 8C illustrate maps of the total intensity I_{TOTAL} and angle θ between the direction of laser polarization and the armchair direction of the sample, respectively (scale bar is 5 μm), according to one or more embodiments of the present disclosure.

FIG. 8D illustrates maps of the total intensity I_{TOTAL} and angle θ between the direction of laser polarization and the armchair direction of the sample, respectively (scale bar is 5 μm), according to one or more embodiments of the present disclosure.

FIG. 8E illustrates maps of the I_{TOTAL} and θ of the area shown in FIG. 8B (scale bar is 5 μm), according to one or more embodiments of the present disclosure.

FIG. 8F illustrates maps of the I_{TOTAL} and θ of the area shown in FIG. 8B (scale bar is 5 μm), according to one or more embodiments of the present disclosure.

FIG. 9A illustrates PL spectra of MoS₂ and its corresponding spatial modulation as shown in the inset contour color map, according to one or more embodiments of the present disclosure.

FIG. 9B illustrates spatial maps of the A_{1g} and E_{2g} peak position, according to one or more embodiments of the present disclosure.

FIG. 9C illustrates the extracted MoS₂Raman spectra from the WSe₂—MoS₂ junction, where the colored spectra corresponds to the inset contour color map in FIG. 9(A), according to one or more embodiments of the present disclosure.

FIG. 9D illustrates maps showing PL intensity and the spatial modulation of photon energy for a selected heterojunction, according to one or more embodiments of the present disclosure.

FIG. 9E illustrates maps showing PL intensity and the spatial modulation of photon energy for a selected heterojunction, according to one or more embodiments of the present disclosure.

FIG. 9F illustrates spectra 1 to 9 collected from the location marked in FIG. 9(D), according to one or more embodiments of the present disclosure.

FIG. 10A illustrates SKPM image showing the surface potential distribution for the WSe₂—MoS₂ heterostructure with the inset showing the AFM height images and no obvious height difference being observed from the two sides of the junction, according to one or more embodiments of the present disclosure.

FIG. 10B illustrates an optical image for the WSe₂—MoS₂ p-n junction device (scale bar, 4 μm), according to one or more embodiments of the present disclosure.

FIG. 10C illustrates electrical transport curves (I versus V) with and without light exposure (1 mW/cm²) showing the presence of a p-n junction and photovoltaic effect, according to one or more embodiments of the present disclosure.

FIG. 10D illustrates electrical transport curves for Ti-contacted MoS₂ and Pd-contacted WSe₂ separately, according to one or more embodiments of the present disclosure.

FIG. 11a illustrates OM images showing obvious color contrast, according to one or more embodiments of the present disclosure.

FIG. 11b illustrates an AFM image showing some small MoS₂ particles growing on WSe₂ sides as indicated in the yellow dashed line area, according to one or more embodiments of the present disclosure.

FIG. 11c illustrates the Raman spectra taken from WSe₂ (black spot) and surrounding particles (red spot), according to one or more embodiments of the present disclosure.

FIG. 11d illustrates a PL and Raman spectra showing that under S rich condition there is an overlapped region where WSe₂ and MoS₂ coexisted as marked with enclosed blue dashed lines, according to one or more embodiments of the present disclosure.

FIG. 11e illustrates the formation of WS₂ in WSe₂ area as shown via the red curve, according to one or more embodiments of the present disclosure.

FIG. 12a illustrates an OM image of the monolayer WSe₂—MoS₂ in-plane heterostructure, according to one or more embodiments of the present disclosure.

FIG. 12b illustrates Raman spectrum taken from inner WSe₂ and outer MoS₂ regions, showing the Raman peaks at 405 cm⁻¹ and 385.7 cm⁻¹ are identified as the A_{1g} and E_{2g} vibration modes from MoS₂ and the prominent peak at 250 cm⁻¹ with a small shoulder is the Raman A_{1g} feature of WSe₂, according to one or more embodiments of the present disclosure.

FIG. 12c illustrates PL spectrum taken from inner WSe₂ and outer MoS₂ regions, according to one or more embodiments of the present disclosure.

FIG. 12d illustrates Raman mappings constructed by the intensity of A_{1g} mode for WSe₂ and MoS₂ at 250 cm⁻¹, according to one or more embodiments of the present disclosure.

FIG. 12e illustrates Raman mappings constructed by the intensity of A_{1g} mode for WSe₂ and MoS₂ at 450 cm⁻¹, according to one or more embodiments of the present disclosure, according to one or more embodiments of the present disclosure.

FIG. 12f illustrates combined Raman mappings of FIGS. 12d and 12e, according to one or more embodiments of the present disclosure.

FIG. 13a illustrates the EELS line scan across the coherence interface from MoS₂ to WSe₂ domains along the green line indicated, according to one or more embodiments of the present disclosure.

FIG. 13b illustrates a spectral image showing the discrete chemical composition at the interface, according to one or more embodiments of the present disclosure.

FIG. 13c illustrates the extracted EEL spectra of MoS₂, according to one or more embodiments of the present disclosure.

FIG. 13d illustrates the extracted EEL spectra of WSe₂, according to one or more embodiments of the present disclosure.

FIG. 14 illustrates a schematic view of the setup for SHG measurement in heterostructure, according to one or more embodiments of the present disclosure.

FIG. 15 illustrates an optical microscopy image showing that MoS₂ growth originates from WSe₂ edges, according to one or more embodiments of the present disclosure.

FIG. 16a illustrates PL measurement on isolated MoS₂, according to one or more embodiments of the present disclosure.

FIG. 16b illustrates photon energy mapping on isolated MoS₂, according to one or more embodiments of the present disclosure.

FIG. 16c illustrates the PL spectra taken from the isolated MoS₂ monolayers (not grown from WSe₂ edges) with only a small variation in PL photon energy from about 1.86 eV to about 1.87 eV being observed, according to one or more embodiments of the present disclosure.

FIG. 17a illustrates a Raman measurement of WSe₂ region in heterostructure showing photon intensity, according to one or more embodiments of the present disclosure.

FIG. 17b illustrates a Raman measurement of WSe₂ region in heterostructure showing photon mapping, according to one or more embodiments of the present disclosure.

FIG. 17c illustrates a Raman measurement of WSe₂ region in heterostructure showing Raman peak position mapping of the corresponding WSe₂ region, according to one or more embodiments of the present disclosure.

FIG. 18a illustrates PL spectra of WSe₂, with the inset showing PL intensity mappings before sulfurization of isolated WSe₂ monolayer, according to one or more embodiments of the present disclosure.

FIG. 18b illustrates PL spectra of WSe₂ monolayer after gas phase sulfurization, with the inset showing PL intensity mappings, according to one or more embodiments of the present disclosure.

FIG. 19 illustrates depletion width estimation by analyzing the first derivative of potential curve from SKPM and a line profile (right) showing the potential change across the WSe₂—MoS₂ heterojunction, according to one or more embodiments of the present disclosure.

FIG. 20 illustrates the rectification character of the WSe₂/MoS₂ heterojunction with the I_{DS}-V_{DS} characteristic curves of the heterojunction without light illumination and the red dashed line indicating the threshold voltage of about 9 V under forward bias, according to one or more embodiments of the present disclosure.

FIG. 21a illustrates an optical image of the selected WSe₂—MoS₂ p-n junction device showing electrical properties of the devices based on heterojunction, according to one or more embodiments of the present disclosure.

FIG. 21b illustrates a graphical view of the electrical transport curves (I vs. V) with (red) and without (black) light exposure (1 mW/cm²) showing the presence of a p-n junction and photovoltaic effect, according to one or more embodiments of the present disclosure.

### DETAILED DESCRIPTION

The invention of the present disclosure relates to solar cells. In particular, the solar cells of the present invention include two-dimensional (2D) monolayer p-n lateral heterojunctions with atomically sharp interfaces. Current complimentary metal-oxide semiconductor (CMOS) techniques for developing junctions, such as ion implantation and thermal diffusion, cause undesired dopant diffusion at the interface, giving rise to an unfavorable dopant concentration gradient near the junction interface that limits ideal p-n junctions. The solar cells of the present invention, however, include a 2D monolayer p-n lateral heterojunctions with an atomically sharp and abrupt interface between semiconductors without interdiffusion of atoms.

The solar cells of the present invention can exhibit unprecedented photovoltatic properties. The solar cells of the present invention can be connected in parallel to achieve extraordinarily high power conversion efficiencies (PCE). The PCE of the solar cells of the present invention are higher than any other vertical and/or lateral 2D monolayer-based photovoltaic device reported to date, offering potential for high integration level. The solar cells of the present invention can be designed as large-scale solar modules. In some embodiments, the solar cells of the present invention can exhibit a PCE of 1.78% under AM 1.5G illumination and 1.83% under 1200 W/m² light intensity.

The solar cells of the present invention can also achieve unprecedented omnidirectional light harvesting capability with extraordinarily high efficiencies maintained at high angles of incidence (AOI). This is unobtainable for conventional vertical solar cells, as significant light scattering or reflection can occur for these conventional solar cells at high AOI. With respect to the solar cells of the present invention, light can directly reach the active area of the device and thus can be highly absorbed from any direction due to the solar cell's atomically thin-layered nature. In some embodiments, the solar cells of the present invention can exhibit exceptional omnidirectional light harvesting behavior with only a 10% loss of PCE at AOI of up to 75°.

The solar cells of the present invention further achieve gate-tuning controllability and environment-independent PCE with optimal electrode spacing. While efficient gate control of van der Waals heterojunction-based devices require dual-gate design at both top and bottom sides of the device, the solar cell of the present invention only requires a single-gate design. The solar cells of the present invention can exhibit efficient back-gate-control that can be tuned for practical use without sacrificing precious active surface area. By controlling the design of electrode spacing and the heterojunction interface location, the solar cells of the present invention can further prevent and/or eliminate performance and sensitivity degradation resulting from chemical gas adsorption, doping, and oxidation phenomena. Proper design of electrode spacing can provide environment-independent PCE as a solution to gas-independent 2D monolayer-based devices without surface passivation.

Accordingly, embodiments of the present disclosure describe solar cells, as well as methods of making solar cells. More specifically, embodiments of the present disclosure describe a solar cell comprising a first monolayer and a second monolayer, the first monolayer and the second monolayer forming a monolayer p-n lateral heterojunction with an atomically sharp interface, and a substrate, the substrate and the monolayer p-n lateral heterojunction forming a solar cell. Embodiments of the present disclosure further describe methods of making a solar cell, for example, by controlling epitaxial growth of the first and second monolayer lateral junction. The method of making the solar cell comprises growing a first monolayer on a first substrate and growing a second monolayer on the first substrate sufficient to form a monolayer p-n lateral heterojunction with an atomically sharp interface. The method further comprises transferring the monolayer p-n lateral heterojunction from the first substrate to a second substrate sufficient to form a solar cell.

### Definitions

As used herein, “AFM” refers to atomic force microscopy.

As used herein, “deposit,” “deposited,” and “depositing” refers to growing, epitaxially growing, depositing, depositing via chemical vapor deposition, epitaxy, etching, doping, thermal oxidation, sputtering, casting, spin-coating, evaporating, evaporating via electron beam evaporation, applying, treating, and any other technique and/or method known to a person skilled in the art.

As used herein, “heterojunction” refers to the interface between two dissimilar semiconductors.

As used herein, “heterostructure” refers to a combination of two or more heterojunctions in a device.

As used herein, “PL” refers to photoluminescence.

As used herein, “solar cell” refers to a device that converts energy of light into electricity via the photovoltaic effect. Solar cell can refer to and/or include a photodetector and/or a photovoltaic cell.

As used herein, “STEM” refers to scanning transmission electron microscopy.

Embodiments of the present disclosure describe solar cells and methods of making solar cells. Embodiments of the present disclosure describe solar cells comprising a first monolayer and a second monolayer, the first monolayer and the second monolayer forming a monolayer p-n lateral heterojunction with an atomically sharp interface; and a substrate, the substrate and the monolayer p-n lateral heterojunction forming a solar cell.

The first monolayer and the second monolayer can be a two-dimensional transition metal dichalcogenide. In some embodiments, the first monolayer and the second monolayer can be characterized by the formula MX₂, wherein M is one or more of molybdenum (Mo) and tungsten (W) and X is one or more of selenium (Se) and sulfur (S). In some embodiments, the first monolayer is one or more of WSe₂, WS₂, MoS₂, and MoSe₂. In some embodiments, the second monolayer is one or more of WSe₂, WS₂, MoS₂, and MoSe₂. In some embodiments, the first monolayer is WSe₂ and the second monolayer is MoS₂.

The monolayer p-n lateral heterojunction with an atomically sharp interface can be two dimensional. In some embodiments, the monolayer p-n lateral heterojunction can be characterized as a planar structure. In some embodiments, the monolayer p-n lateral heterojunction is atomically thin. In some embodiments, the monolayer p-n lateral heterojunction can include an atomically sharp interface. In some embodiments, the monolayer p-n lateral heterojunction can include an atomically sharp interface without interdiffusion of atoms. In some embodiments, the monolayer p-n lateral heterojunction can include an atomically sharp and abrupt interface between semiconductors. In some embodiments, the monolayer p-n lateral heterojunction is a 2D monolayer WSe₂—MoS₂ p-n lateral heterojunction.

The first substrate and the second substrate can be one or more of a solid, a crystalline solid, amorphous, and a liquid. The first substrate and the second substrate can include any type of semiconducting material, compound, and/or element. The first substrate and the second substrate can be one or more of a Group IV elemental semiconductor, Group IV compound semiconductor, Group VI elemental semiconductor, III-V semiconductor, II-VI semiconductor, I-VII semiconductor, IV-VI semiconductor, IV-VI semiconductor, V-VI semiconductor, II-V semiconductor, I-III-VI₂ semiconductor, layered semiconductor, magnetic semiconductor, and charge-transfer semiconductor. The first substrate and the second substrate can include one or more of a tertiary compound, oxide, and alloy. The first substrate and the second substrate can include one or more of any element of the periodic table. The first substrate and the second substrate can include an organic compound. The semiconducting substrate can include one or more of zinc, cadmium, aluminum, gallium, indium, thallium, carbon, silicon, germanium, tin, lead, arsenic, antimony, bismuth, sulfur, selenium, tellurium, and polonium. In some embodiments, the first substrate is sapphire. In some embodiments, the second substrate is a SiO₂/Si substrate.

The solar cell can further comprise one or more electrodes. The electrodes can include any type of electrode and include any type of material, compound, and/or element known in the art as functioning as an electrode. In some embodiments, the electrodes include one or more of titanium, gold, and palladium. In some embodiments, the electrodes include a Ti/Au electrode and a Au electrode. In some embodiments, the electrodes include a Ti/Au electrode and a Pd electrode.

In some embodiments, one or more solar cells can be connected in parallel to achieve unprecedented power conversion efficiency. In some embodiments, the solar cells can achieve a power efficiency of about 1.78% under AM 1.5G illumination. In some embodiments, the solar cells can achieve a power efficiency of about 1.83% under 1200 W/m² light intensity. In some embodiments, the solar cells harvest omnidirectional light with only a 10% loss of PCE at high angles of incidence of up to 75°. In some embodiments, the solar cell exhibits an environment-independent photovoltaic effect. In some embodiments, the solar cell exhibits environment independent PCE as a solution to gas-independent 2D monolayer-based devices without surface passivation. In some embodiments, the solar cell exhibits gate-tuning controllability. In some embodiments, the solar cell has a large surface area. In some embodiments, the solar cell is used for chemical gas adsorption. In some embodiments, the solar cell functions as a gas sensor.

The electrical transport properties of the solar cell of the present invention can be dependent and/or highly dependent on electrode spacing, as the active area and carriers collection can depend on distance. The gate-controlling behavior and gas-dependent effect of the solar cell of the present invention can vary by electrode spacing under different gate bias and gas environments. As the electrode spacing increases, current can decrease, while the strength of the gate-controlling behavior increases. Conversely, as electrode spacing decreases, current can increase, while the strength of the gate-controlling behavior decreases. The gate controlling properties of the monolayer p-n lateral heterojunction can be attributed to the difference in electron mobilities and intrinsic doping levels between the first monolayer and the second monolayer.

Similarly, the gas-dependent effect of the solar cell of the present invention can vary by electrode spacing under different gate bias and gas environments. As the electrode spacing distance increases, the surface defect sites responsible for gas interaction can also increase. However, as electrode spacing decreases, about constant PCE can be obtained under air, vacuum, and O₂-rich environments, indicating the solar cell can be environment-independent. This environment-independent property can serve not only to maintain high-performance under various ambient conditions, but can also avoid further passivation layers that complicate the fabrication process and limit the light absorption properties of the underlying monolayers. In some embodiments, reducing the electrode spacing to about nanometers can lead to ideal defect-free lateral heterojunctions.

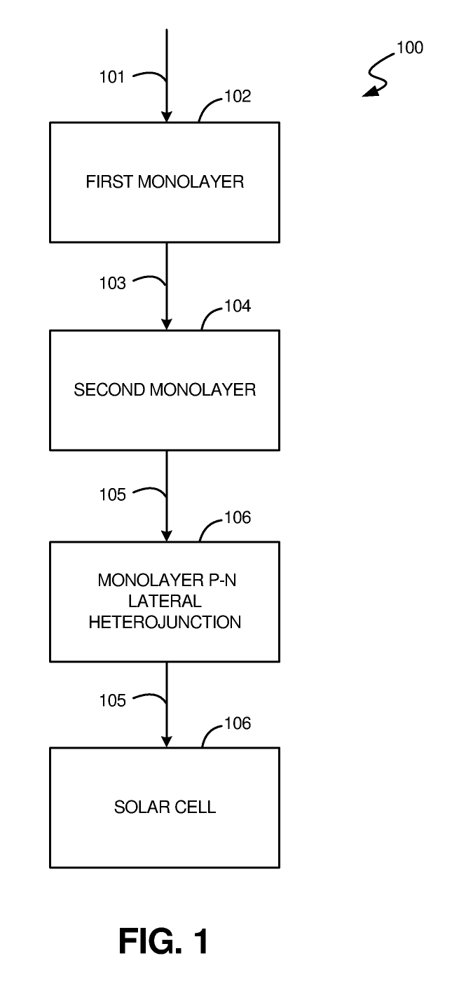

Another embodiment of the present disclosure further describes a method of making a solar cell. FIG. 1 illustrates a block flow diagram of a method of making a solar cell, according to one or more embodiments of the present disclosure. As shown in FIG. 1, a method of making a solar cell comprising growing 101 a first monolayer on a first substrate 102; growing 103 a second monolayer on the first substrate 104 sufficient to form a monolayer p-n lateral heterojunction with an atomically sharp interface 106; and transferring 107 the monolayer p-n lateral heterojunction from the first substrate to a second substrate sufficient to form a solar cell 108. The above discussion applies and is hereby incorporated by reference in full.

Growing 101 and growing 103 can include one or more of growing via epitaxy and depositing. Depositing can include one or more of growing, epitaxy, van der Waals epitaxy, epitaxially growing, epitaxially growing via chemical vapor deposition, depositing, etching, doping, thermal oxidation, sputtering, casting, spin-coating, evaporating, evaporating via electron beam evaporation, applying, and treating. In some embodiments, the growing 101 and growing 103 can include controlled two-step epitaxially growth via chemical vapor deposition.

In some embodiments, growing a first monolayer on a first substrate can include one or more sources, one or more gases, and a substrate. In some embodiments, growing the first monolayer on the first substrate can include placing the one or more sources, one or more gases, and the substrate in a furnace. In some embodiments, growing the first monolayer on the first substrate can include the one or more sources can being placed in one or more quartz boats and a gas feed stream being introduced into the furnace. In some embodiments, growing the first monolayer can include heating under pressure for a period before cooling to about room temperature.

In some embodiments, growing a second monolayer on the first substrate sufficient to form a monolayer p-n lateral heterojunction with an atomically sharp interface can include one or more sources, one or more gases, and a substrate. In some embodiments, growing the second monolayer on the first substrate can include placing the one or more sources, one or more gases, and the substrate in a furnace. In some embodiments, growing the second monolayer on the first substrate can include the one or more sources can being placed in one or more quartz boats and a gas feed stream being introduced into the furnace. In some embodiments, growing the second monolayer can include heating under pressure for a period before cooling to about room temperature.

An important feature of the present invention is the ability to control the growth of monolayers to form a monolayer p-n lateral heterojunction with an atomically sharp interface and without alloy formation at the interface. In some embodiments, growing the first monolayer can occur at a high temperature, whereas growing the second monolayer can occur at a lower temperature and in a different furnace to prevent and/or control substitutional diffusion at the junction interface. In some embodiments, controlling the growth of the first and second monolayers to form a monolayer p-n lateral heterojunction can be achieved by controlling the relative vapor amount of the one or more sources used in growing the second monolayer. In some embodiments, controlling the growth of the first and second monolayers to form a monolayer p-n lateral heterojunction can be achieved by controlling the relative vapor amount of the one or more sources used in growing the first monolayer.

In some embodiments, the one or more sources can include various powders. In some embodiments, the one or more sources can include one or more of WO₃ powders, Se powders, MoO₃ powders, and S powders. In some embodiments, the one or more gases can include one or more of argon and hydrogen. In some embodiments, the first substrate can include sapphire.

The following Examples are intended to illustrate the above invention and should not be construed as to narrow its scope. One skilled in the art will readily recognize that the Examiners suggest many other ways in which the invention could be practiced. It should be understand that numerous variations and modifications may be made while remaining within the scope of the invention.

### Example 1

### A 2D Monolayer WSe₂—MoS₂ P-N Lateral Heterojunction

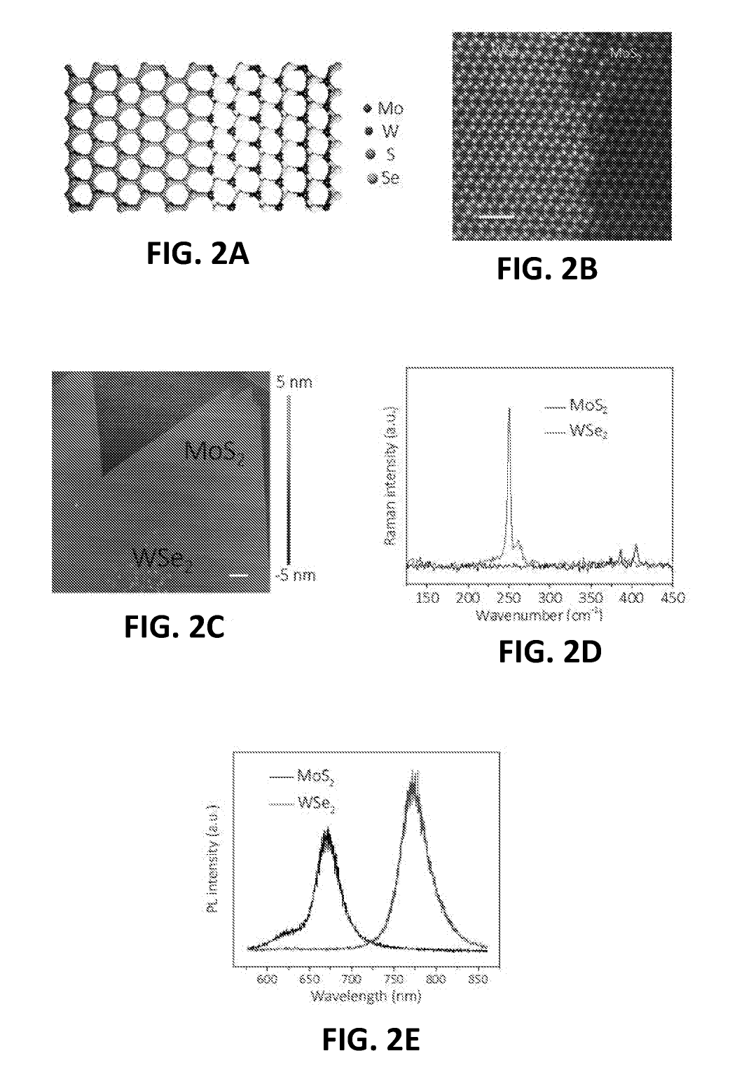

Growth and characterization of monolayer WSe₂—MoS₂ lateral heterostructures. The monolayer WSe₂—MoS₂ lateral heterostructure was epitaxially grown on sapphire substrates by two-step chemical vapor deposition of WSe₂ at 925° C. and MoS₂ at 755° C. FIG. 2a illustrates a high resolution STEM image of monolayer WSe₂—MoS₂ lateral heterostructures, according to one or more embodiments of the present disclosure. Single crystal WSe₂ monolayer was first grown by placing WO₃ powders in a quartz boat at the heating zone center of the furnace. The sapphire substrate was placed at the downstream side next to the quartz boat. Se powders were placed in a separate quartz boat at the upper stream side of the furnace and the temperature was maintained at about 260° C. during the reaction. Ar/H₂ flow was controlled at Ar=about 90 sccm and H₂=about 6 sccm with the chamber pressure of about 20 Torr. The heating zone was heated to about 925° C., kept for about 15 min, and cooled down to about room temperature. Then the sample was moved to a separate furnace. The MoS₂ synthesis was carried out by switching the sources to MoO₃ and S powders. The Ar flow was controlled at about 70 sccm with the chamber pressure of about 40 Torr. The center zone and S source were heated to about 725° C. and about 190° C., respectively, and kept for about 15 min. Finally, the sample was cooled down to about room temperature. Surface morphology and surface potential of the heterostructures were characterized using a commercial atomic force microscope (Cypher ES—Asylum Research Oxford Instruments). Raman spectra were collected in a Witec alpha 300 confocal Raman microscopic system including RayShield coupler with exciting laser wavelength of 532 nm. The laser spot-size is around 0.5 μm. Raman signal was collected by a 100× objective lens (N.A=0.9) from Carl Zeiss Microscopy GmbH and dispersed by a 1800 lines/mm grating for Raman measurement and a 300 lines/mm grating for PL measurements. PL measurement was also performed in the Witec alpha 300 confocal system.

Fabrication and characterization of devices. The monolayer WSe₂—MoS₂ lateral heterojunction was first transferred onto a SiO₂ (260 nm)/Si substrate by a PMMA (950 A4, MicroChem) assisted method. The monolayer WSe₂—MoS₂ lateral heterojunction-based device was defined with electron-beam lithography in a SEM system (JEOL JSM-7001F). Ti/Au (10/20 nm) and Au (20 nm) were deposited using electron beam evaporation. The measurement was carried out in a Lakeshore cryogenic probe-station (PS-100) and measured by Keithley 4200 with an AM 1.5G light source.

Device simulation model. The current characteristics of the monolayer WSe₂—MoS₂ lateral heterojunction were simulated with the drift-diffusion model coupled with a two-dimensional Poisson solver, implemented in the finite element solver COMSOL 3.5a. A schematic of the device simulated is shown in FIG. 6 and the governing Poisson and current continuity equations are, respectively:

∇·(ε₀εᵣ∇φ)=q(n−p+N_{A}−N_{D}) (6)

∇·Jₙ=∇·(−qnμₙ∇φ+qDₙ∇n)=qRₙ (7)

∇·J=∇·(−qnμₚ∇φ−qDₚ∇p)=−qRₚ (8)

The relative permittivity εᵣ is 4 for both materials and the electron and hole concentrations n and p were calculated based on the electron dispersions of the monolayer 2D materials with respect to the potential profile φ. N_{A} and N_{D} were the acceptor and donor concentrations and q was the elementary charge constant. J, μ, D and R were the current density, mobility, diffusion coefficient and recombination rates for the different carriers, respectively. More specifically, qD=k_{B}Tμ with k_{B} being the Boltzmann constant and T=300 K and the significant recombination mechanism was Shockley-Read-Hall, i.e. R≈np/τ(n+p) with r being the carrier life-time of 50 μs. Additionally, the work function of MoS₂ was 0.675 eV lower than that of WSe₂ which is included in the simulation model.

### DISCUSSION

The photovoltaic (PV) properties of monolayer WSe₂—MoS₂ p-n lateral heterojunction were investigated. In particular, a solar cell based on an atomically-sharp 2D monolayer WSe₂—MoS₂ p-n lateral heterojunction was synthesized by two-step epitaxial growth. PCE up to about 1.78% under AM 1.5G illumination and about 1.83% under 1200 W/m² light intensity were achieved by connecting two cells in parallel, setting the world record for high efficiency among vertical and lateral 2D monolayer-based solar cells and demonstrating potential for high integration level. In addition, owing to the full exposure of the depletion region at the surface and planar structure, the solar cell exhibited excellent omnidirectional light harvesting behavior with only about a 10% loss of PCE at high angles of incidence (AOIs) of 75°, which is unachievable for conventional vertical solar cells. Additionally, the temperature dependent open-circuit voltage and short-circuit current of the cell can be modeled by typical p-n junctions, suggesting a high degree of integration with conventional semiconductors. The temperature-dependent dark current, open-circuit voltage, and short-circuit current properties were modeled using typical p-n junction models, greatly increasing the feasibility of layered 2D-based devices. In addition, proper design of electrode spacing indicated environment-independent PCE as a solution to gas-independent 2D monolayer-based devices without surface passivation. These properties combining inherent atomic thickness and lateral p-n heterojunction hold the promise for the development of next-generation of layered 2D-based devices. The solar cells can function as nanoscale solar cell devices, water splitting devices, and flexible electronics.

After the growth processes, atomic force microscopy (AFM), scanning transmission electron microscopy (STEM), photoluminescence (PL), and Raman measurements were carried out to characterize the as-grown lateral heterostructures. FIG. 2b illustrates an AFM image of monolayer WSe₂—MoS₂ lateral heterostructures (scale bar, 1 nm), according to one or more embodiments of the present disclosure. As shown in FIG. 2b, the annular dark field image obtained with STEM indicates lateral heterojunction, featuring an atomically-sharp interface without interdiffusion of atoms, which is vital for preserving optoelectronic/electrical properties driven by the intralayer coupling. Although sharp and abrupt interface between semiconductors are desirable to form either homojunctions or heterojunctions, the current CMOS techniques used to develop the junctions such as ion implantation and thermal diffusion cause undesired dopant diffusion at the interface, leading to unfavorable dopant concentration gradient near junction interface that limit ideal p-n junctions. However, the growth of MoS₂ surrounding WSe₂ was promoted by unsaturated dangling bonds at peripheral edges of triangular domains. Additionally, after WSe₂ growth at high temperature, the subsequent MoS₂ growth was operated at low temperature, preventing substitutional diffusion at junction interface. FIG. 2b also shows that more W atoms are located at the interface, suggesting that the growth starts from the replacement of Se atoms by S atoms at WSe₂ edge. On the other hand, although no atomic interdiffusion exists for interlayer coupling in vdW-based heterostructures, significant radiative recombination of spatially indirect excitons existed against PV carrier generation.

FIG. 2c illustrates a monolayer WSe₂—MoS₂ lateral heterostructures (scale bar, 1 μm, according to one or more embodiments of the present disclosure. As shown in FIG. 2c, the AFM images of the as-fabricates monolayer WSe₂—MoS₂ heterostructure showed negligible height difference between WSe₂ and MoS₂ regions, suggesting atomically lateral growth of the monolayer heterostructures.

To confirm the WSe₂ and MoS₂ chemical composition, Raman spectroscopy was performed. FIG. 2d illustrates a graphical view of Raman spectroscopy of MoS₂ and WSe₂ regions, according to one or more embodiments of the present disclosure. The Raman peak at 250 cm¹ measured from the WSe₂ region was the A_{1g} characteristic peak of WSe₂, and the Raman peaks at 405 cm⁻¹ and 385 cm⁻¹ from the MoS₂ region were A_{1g} and E_{2g} characteristic peaks of MoS₂.

To further confirm the monolayer WSe₂—MoS₂ lateral heterostructures, PL spectroscopy was performed. FIG. 2e illustrates a graphical view of photoluminescence of MoS₂ and WSe₂ regions, according to one or more embodiments of the present disclosure. As shown in FIG. 2e, the peaks at 672 nm and 778 nm corresponded with the direct band gaps of monolayer MoS₂ (˜1.8 eV) and WSe₂ (˜1.6 eV), respectively.

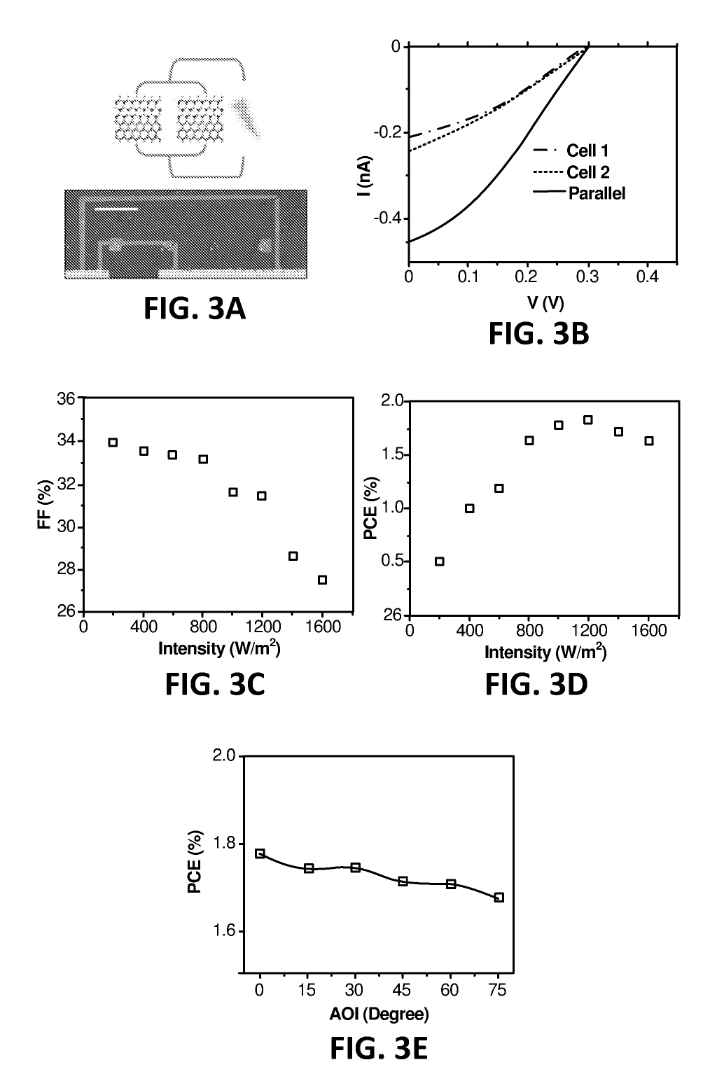

To fabricate the PV devices based on monolayer p-n lateral heterostructures, as-grown monolayer WSe₂—MoS₂ lateral heterostructures were transferred onto the SiO₂ (260 nm)/Si substrate. FIG. 3a illustrates a schematic view and SEM image of monolayer WSe₂—MoS₂ lateral heterojunction photovoltaic devices connected in parallel (scale bar, 50 μm), according to one or more embodiments of the present disclosure. Ti/Au (10/20 nm) and Au (20 nm) electrodes were then patterned by electron beam lithography and deposited by electron beam evaporation to form ohmic contacts with MoS₂ and WSe₂, respectively. The active area of the device was defined as the summation of the multiplication of electrode width and electrode spacing of the two devices, which are 10 μm×2 μm for cell 1 and 5 μm×4 μm for cell 2 (FIG. 3a).

FIG. 3b illustrates a graphical view of I-V characteristics of monolayer WSe₂—MoS₂ lateral heterojunction photovoltaic devices connected separately and in parallel under AM 1.5G light illumination, according to one or more embodiments of the present disclosure. As listed in Table 1, the interconnection of the 2 cells in parallel yielded an I_{sc} of 0.45 nA, which is equal to the sum of the cells measured separately.

TABLE 1
PV properties of the single atomically sharp monolayer WSe₂-MoS₂ lateral
heterojunction solar cells shown in FIG. 3a.

| Devices | V_{oc} (V) | I_{sc} (nA) | FF (%) | PCE (%) |
|---|---|---|---|---|
| Cell 1 | 0.29 | 0.21 | 35.3 | 1.07 |
| Cell 2 | 0.30 | 0.24 | 29.1 | 1.05 |
| 2 Cells in Parallel | 0.30 | 0.45 | 31.6 | 1.78 |
| (Cell 1 and Cell 2) | | | | |

The PCE of this parallel solar cells was 1.78%, which is higher than any other individual 2D monolayer-based solar cells reported up to date. This result indicated that the device can be effectively devised into large scale solar modules to achieve performance comparable to conventional solar devices. Vertically-stacked vdW 2D monolayer-based heterostructures such as MoS₂/graphene, MoS₂/WSe₂ and WS₂/MoS₂ have been reported as PV devices with efficiencies of ˜1, ˜0.2% and ˜1.5%, respectively. The relatively low efficiencies were attributed to serious radiative recombination of spatially indirect excitons at vertically-stacked vdW interfaces. Nevertheless, this radiative recombination of vertically-stacked heterojunctions can be minimized by the atomically sharp interface of the heterostructure.

To further characterize the PV properties of the paralleled device, the filling factor (FF) and the PCE are presented as functions of illumination intensity in FIGS. 3c and 3d, respectively. FIG. 3c illustrates a graphical view of light intensity dependent FF of monolayer WSe₂—MoS₂ lateral heterojunction photovoltaic devices connected in parallel under AM 1.5G light illumination, according to one or more embodiments of the present disclosure. FIG. 3d illustrates a graphical view of power conversion efficiency of monolayer WSe₂—MoS₂ lateral heterojunction photovoltaic devices connected in parallel under AM 1.5G light illumination, according to one or more embodiments of the present disclosure. As the light intensity increases, additional charge carriers were induced, enhancing open-circuit voltage (V_{oc}), short-circuit current density (J_{sc}) and thus PCE. Nevertheless, increasing the light intensity also prompted more charge recombination events, reducing FF and thus PCE. Accordingly, the device exhibited the highest PCE of 1.83% at 1200 W/m² light intensity, which is the highest efficiency being reported among 2D monolayer-based vertical and lateral heterojunction. Such high PCE can be attributed to the high quality atomically-sharp interface and the enhanced performance of the parallel cell design.

Additionally, the omnidirectional light harvesting behavior of the parallel solar cells was characterized by monitoring the PV characteristics under different AOIs. FIG. 3e illustrates a graphical view of angular dependent power conversion efficiency of monolayer WSe₂—MoS₂ lateral heterojunction photovoltaic devices connected in parallel under AM 1.5G light illumination, according to one or more embodiments of the present disclosure. It was expected that at large AOIs, significant light scattering or reflection occur in conventional vertical solar cells. For example, planar Si-based optical devices showed more than 90% efficiency reduction when being operated under high AOIs (75°) as compared with the light being incident normally (0°) due to high scattering and reflection at the top planar surface. In contrast, for lateral heterojunction photodiodes, light can directly reach the device active area, and thus highly absorbed from any directions due to atomically-thin layered nature. Therefore, the actual power densities at the junction were nearly identical at high AOIs and thus give rise to only 10% of efficiency reduction at 750 in the device.

For a typical p-n junction based solar cell, the temperature dependence of V_{oc} can be calculated according to the reverse saturation current density (I₀)

$${I}_{0} = q ( \frac{{D}_{n}}{{L}_{n} {N}_{A}} + \frac{{D}_{p}}{{L}_{p} {N}_{D}} ) {n}_{i}^{2} \qquad ( 1 )$$

where nᵢ is the intrinsic carrier density (˜10¹⁰ cm⁻² for both WSe₂ and MoS₂), N_{A} and N_{D} are densities of acceptor and donor atoms, Dₙ and Dₚ are diffusion constants of minority carriers in n and p regions, and Lₙ and Lₚ are diffusion lengths of minority carriers in n and p regions, respectively.²⁹ Since nᵢ can be expressed as

$${n}_{i}^{2} = {AT}^{3} exp ( - \frac{{E}_{g}}{kT} ) \qquad ( 2 )$$

where A is a constant essentially independent of temperature, E_{g} is the band gap of the material, and k is the Boltzmann constant. I₀ and V_{oc} can be expressed as

$$\begin{matrix}{I}_{0} = {BT}^{3} exp ( - \frac{{E}_{g}}{kT} ) & ( 3 ) \\ {V}_{oc} = \frac{kT}{q} ln ( \frac{{I}_{sc}}{{I}_{0}} ) & ( 4 )\end{matrix}$$

By assuming that dV_{oc}/dT does not depend on dI_{sc}/dT, dV_{oc}/dT can be found as

$$\frac{{dV}_{oc}}{dT} = \frac{{V}_{oc} - {V}_{g}}{T} - \frac{3 k}{q} = - \frac{{V}_{g} - {V}_{oc} + \frac{3 kT}{q}}{T} \qquad ( 5 )$$

where V_{g} E_{g}/q. For typical semiconductor such as Si, dV_{oc}/dT is usually negative based on the above equations and dI_{sc}/dT is positive due to decreased bandgap energy (E_{g}).

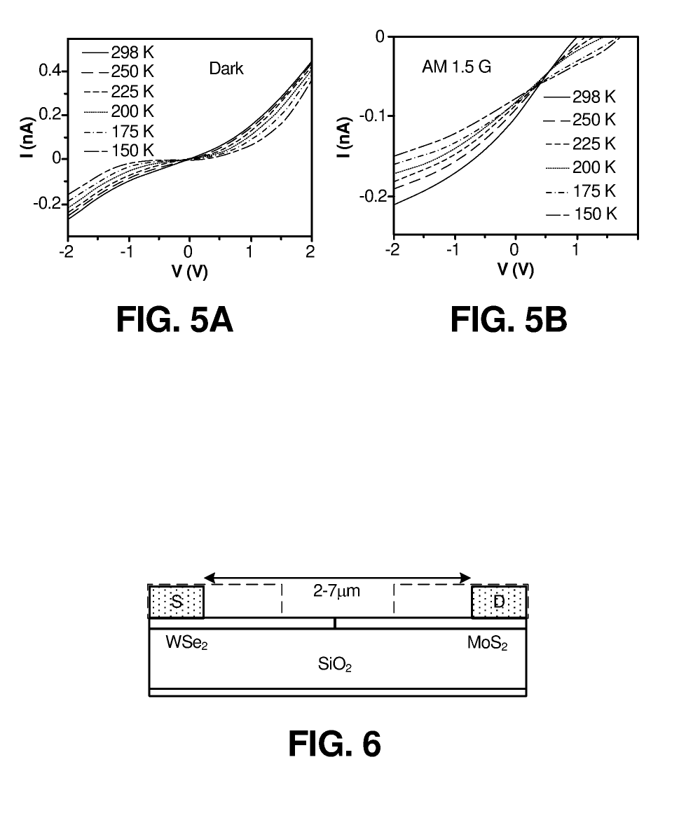

FIGS. 5a and 5b show the temperature-dependent I-V characteristics under dark and AM 1.5G illumination. FIG. 5a is a graphical view of temperature dependent electrical characteristics of monolayer WSe₂—MoS₂ lateral heterojunctions in the dark, according to one or more embodiments of the present disclosure. FIG. 5b is a graphical view of temperature dependent electrical characteristics of monolayer WSe₂—MoS₂ lateral heterojunctions under AM 1.5G illumination, according to one or more embodiments of the present disclosure. At high temperatures, the device exhibited higher dark current, larger J_{sc}, and smaller V_{oc} than at low temperatures, which is consistent with typical semiconductor p-n junctions. Compared with Schottky junctions, p-n junctions were expected to have a stronger temperature dependence due to the exponential dependence of the current density on both temperature and band gap energy. Therefore, the PV effect of the device indeed originated from the WSe₂—MoS₂ lateral heterojunction.

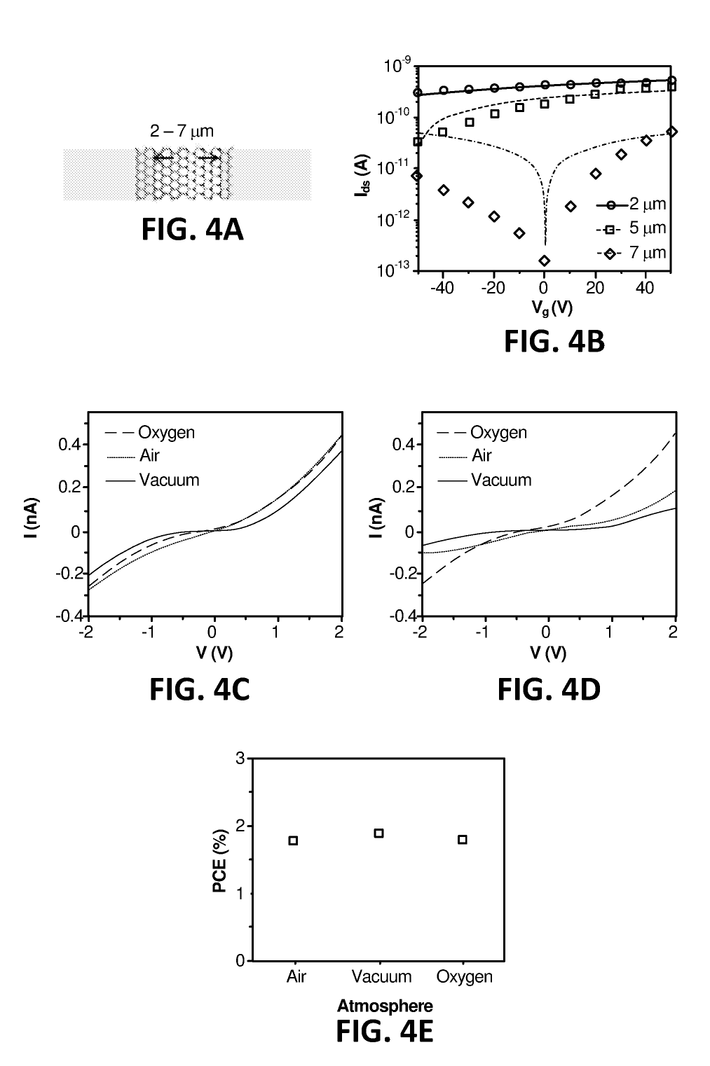

Due to the atomically-sharp interface of the 2D monolayer-based lateral heterojunction, it is possible to design devices beyond the scaling limit. However, the electrical transport properties were expected to be highly dependent on electrode spacing, because the active area and carriers collection depends on distance. Three devices were fabricated with electrode spacing of 2, 5, and 7 μm to study electronic transport properties at different device sizes. FIG. 4a is a schematic view of electrode spacing of monolayer WSe₂—MoS₂ lateral heterojunction, according to one or more embodiments of the present disclosure. By measuring these devices under different gate bias and gases environments, a difference in the gate-controlling and gas-dependent effect was observed.

FIG. 4b illustrates a graphical view of simulated (lines) and experimental (symbols) dark Id-V_{g} characteristics of monolayer WSe₂—MoS₂ lateral heterojunctions at V_{ds} of 2 V with different electrode spacing distances, according to one or more embodiments of the present disclosure. The simulation based on the model (see the details in Methods and FIG. 6) showed good agreement with the measured I_{ds}-V_{g} curves for the cases of 2 and 5 μm. FIG. 6 is a schematic view of a simulated monolayer WSe₂—MoS₂ lateral heterojunction, according to one or more embodiments of the present disclosure. The device with 2 μm electrode spacing exhibited the highest current along with the weakest gate-controlling behavior. Oppositely, the device with 7 μm electrode spacing showed the lowest current and ambipolar gate-controlling properties. The gate controlling properties presented in the lateral heterojunction can be attributed to the difference in electron mobilities and intrinsic doping levels between WSe₂ and MoS₂. It has been reported that MoS₂ is an intrinsically n-doped 2D material, whereas WSe₂ is intrinsically weakly p-doped 2D material and exhibits ambipolar behavior. For the device with 7 μm electrode spacing, the current of the device is limited by the poor electrical conductivity of WSe₂ at 0 V gate bias, which showed significantly low I_{ds} as compared with the device with 2 μm or 5 μm electrode spacing. At high negative gate bias, the doping concentration of WSe₂ increased, leading to the transition to more ideal p-n junction along with improved mobility of WSe₂ and thus the increase of I_{ds}. At high positive gate bias, WSe₂ became n type, leading to the transition to n-n junction. In this case, the mobility of WSe₂ was also enhanced, resulting in the increase of I_{ds}. In the device with 2 μm electrode spacing, however, the gate-controlling phenomenon was absent. This can be attributed to the fact that for shorter drain-source distance, the electric field between the drain-source increases, leading to higher injection current. At such high current, the induced electric field by the gate voltage applied between −50 V and 50 V cannot sufficiently control I_{ds}.

Besides the gate-controlling behavior, the gas doping effect and its distance-dependence on electrode spacing were also of interest in lateral heterojunctions because they can modulate device performance. One of the most discussed gases is oxygen, because O₂ adsorption on 2D materials can attract electrons altering the electrical properties. FIG. 4c illustrates a graphical view of dark I-V characteristics under various ambient conditions (vacuum, air, and O₂-rich) for monolayer WSe₂—MoS₂ lateral heterojunctions with 2 μm electrode spacing distances, according to one or more embodiments of the present disclosure. FIG. 4d illustrates a graphical view of dark I-V characteristics under various ambient conditions (vacuum, air, and O₂-rich) for monolayer WSe₂—MoS₂ lateral heterojunctions with 5 μm electrode spacing distances, according to one or more embodiments of the present disclosure. Unlike most MoS₂ field effect transistors, which exhibit reduced current under air or O₂-rich environments, the monolayer WSe₂—MoS₂ lateral heterostructure-based device exhibited increased current at the V_{ds} range between −2 V and 2 V. This increased current is attributed to the combined effect of O₂ adsorption in MoS₂ and WSe₂. According to a simulation model, an O₂ molecule averagely gain 1.136 electron from WSe₂ and 0.988 electrons from MoS₂. Therefore, under the same ambient condition, O₂ interacted more strongly with WSe₂ than with MoS₂. Since O₂ is typically an electron acceptor, WSe₂ became more heavily doped (more p-type) and the carrier mobility increased, leading to increased current of the device. By increasing the electrode spacing distance, the surface defect sites responsible for gas interaction also increased. Therefore, the device was more strongly affected by ambient gas and the current enhancement in air and O₂-rich environment becomes more significant.

Alternatively, by shortening the electrode spacing to 2 μm, relatively constant PCEs of 1.78, 1.89, and 1.79 were observed under air, vacuum, and O₂-rich environments, respectively, suggesting environment-independent devices. FIG. 4e is a graphical view of power conversion efficiency of a monolayer WSe₂—MoS₂ lateral heterojunction in various ambient environments, according to one or more embodiments of the present disclosure. This environment-independent property served not only to maintain high-performance under different ambient conditions but also avoided further passivation layers that complicate the fabrication process and limit the light abortion properties of the underlying monolayers. It is noteworthy that further reduction of electrode spacing down to few nanometers can eventually lead to ideal defects-free lateral heterojunctions.

In summary, the successful fabrication of atomically-sharp 2D monolayer WSe₂—MoS₂ lateral heterojunction-based solar cells was demonstrated. Due to the uniqueness of the atomically-sharp interface of the planar heterojunction, the world highest PCEs of 1.78% and 1.83% under AM 1.5G and 1200 W/m² light intensity, respectively, were achieved. Moreover, unprecedented omnidirectional light harvesting capability was achieved, with 90% of efficiency maintained at high AOIs up to 75%, which is unobtainable for traditional vertical junction solar cells. The observed V_{oc} and J_{sc} temperature dependence were also well-explained by using typical p-n junction principles. Finally, by optimizing the electrode spacing between to 7 μm and 2 μm, the device showed gate-tuning controllability and environment-independent PCE, respectively. These intriguing characteristics can be the basis for future development of high performance 2D monolayer-based PV devices.

### Example 2

### A Method of Making a 2D Monolayer WSe₂—MoS₂ P-N Lateral Heterojunction

Two-dimensional (2D) transition metal dichalcogenides (2D TMDCs) are of interest for electronics applications in that they offer tunabilty of several properties, including the band gap, band offset, carrier density, and polarity. (The bulk TMDCs have been known for a long time and have not evoked similar interest.) Heterostructures formed by vertical stacking of different 2D TMDCs have been realized via the transfer of their exfoliated or as-grown flakes, where their properties are dominated by the stacking orientation and interlayer coupling strength. However, lateral heterostructures with edge contacts offer easier band offset tuning because the materials are more spatially separated. The direct growth of lateral heterojunctions is challenging because TMDC alloys are thermodynamically preferred. Recently, the MoS₂—MoSe₂, WS₂—WSe₂, WS₂—MoS₂, and MoSe₂—WSe₂ lateral heterostructures with interesting optical and electrical properties were obtained by one-pot synthetic processes. However, the interface regions for these lateral junctions are likely alloy structures because all of the precursors coexist in vapor phases during the growth. Such processes only allow the growth of heterostructures with either different metals or chalcogen, making it difficult to grow p-n heterostructures such as WSe₂—MoS₂.

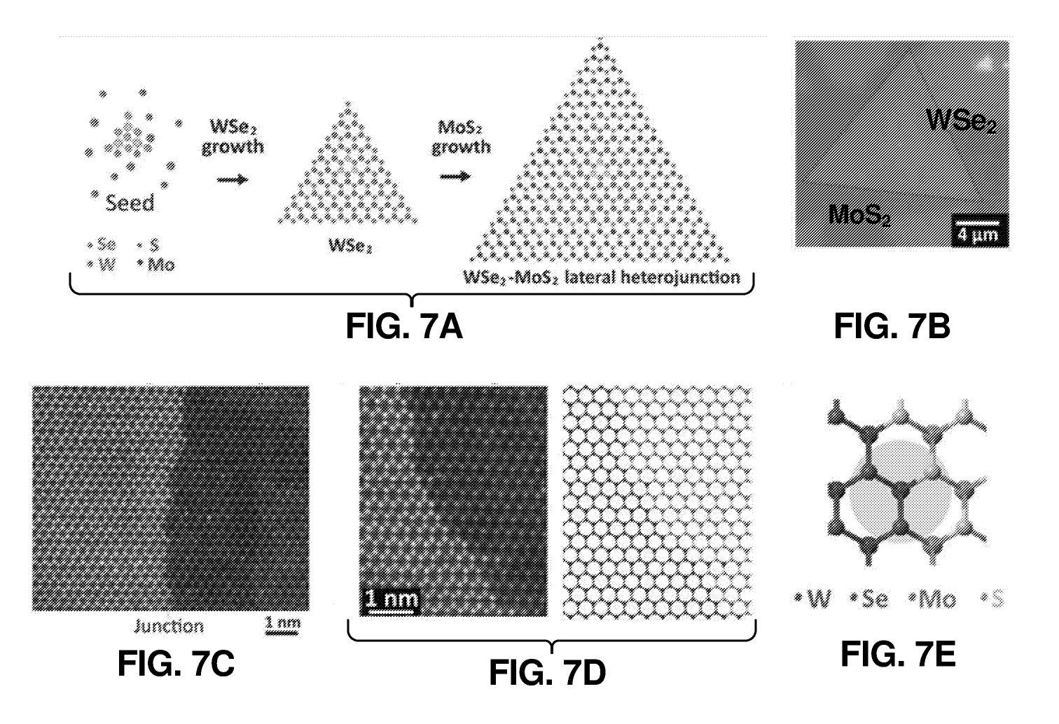

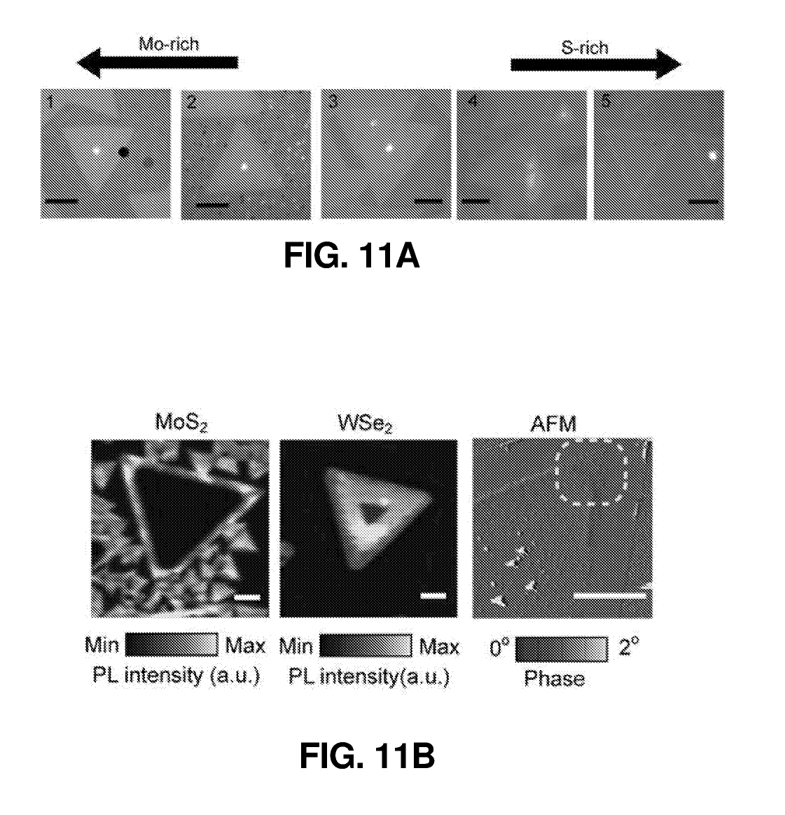

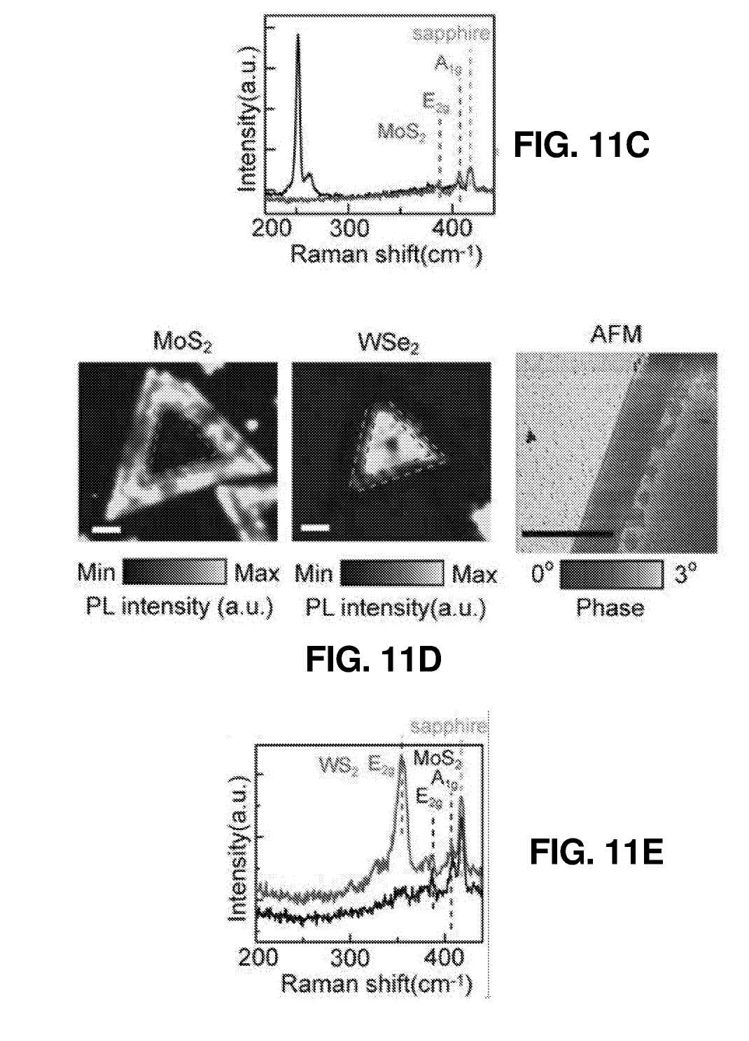

Here, the controlled epitaxial growth of WSe₂—MoS₂ lateral junction is reported, where WSe₂ was grown on substrates through van der Waals epitaxy, followed by the edge epitaxy of MoS₂ along the W growth front. Two-step growth offers precise control to achieve the atomically sharp transition in compositions at the junction. Optical and microscopic characterizations revealed the detailed mechanisms for the regrowth (similar to living growth) for the 2D TMDC systems. The 2D lateral WSe₂—MoS₂ heterojunction was synthesized on c-plane sapphire substrates by sequential chemical vapor deposition (CVD) of WSe₂ and MoS₂ (FIG. 7A). To avoid the alloy reaction observed in one-pot synthesis, a single-crystalline triangular WSe₂ monolayer was first prepared requiring a higher growth temperature (925° C.) and then performed the MoS₂ growth at 755° C. in a separate furnace. The WSe₂ growth proceeds from WSe₂ seeds, followed by van der Waals epitaxy on sapphire. The crucial point for successful heterostructure synthesis without alloy formation was to control the relative vapor amount of MoO₃ and S during the second step MoS₂ growth. The excess in Mo precursors enhanced the MoS₂ vertical growth, whereas the excess in S vapor promoted the formation of undesired WS₂ at the interface (FIG. 11).

More specifically, WSe₂ single crystal monolayer was first grown by the chemical vapor deposition method. The WO₃ powder (0.6 g) was placed in a quartz boat located in the heating zone center of the furnace. The sapphire substrate was put at the downstream side, just next to the quartz boat. The Se powders were placed in a separate quartz boat at the upper stream side of the furnace and the temperature maintained at about 260° C. (during the reaction. The gas flow was brought by an Ar/H₂ (Ar=about 90 seem, H₂=about 6 seem), and the chamber pressure was controlled at about 20 Torr. The center heating zone was heated to about 925° C. After reaching the desired growth temperature of about 925° C., the heating zone was kept for about 15 min. and the furnace was then naturally cooled to about room temperature. After optical characterizations for the as-grown WSe₂, the sample was then put into a separate furnace for the second step MoS₂ growth. The setup for MoS₂ synthesis was similar to WSe₂, by switching the source to MoO₃ powder (0.6 g) and S powders. The Ar gas flow as set at about 70 seem and the pressure was controlled at about 40 Torr. The WSe₂ sample was put at the downstream side of MoO₃ boat and the distance between the sample and quartz boat was about 9 cm for best Mo and S sources ratio to construct a WSe₂/MoS₂ heterojunction. The center zone and S source were heated to about 755° C. and about 190° C. and held for about 15 min. for synthesis, and then naturally cooled to about room temperature.

The WSe₂—MoS₂ heterojunction was first transferred onto a SiO₂ (300 nm)/Si substrate by a poly (methyl methacrylate) (PMMA) (950 PMMA A4, Micro Chem) assisted method. PMMA thin film was spin-coated on top of sample, and then the PMMA/sample/sapphire was dipped in a 6M HF solution to etch the sapphire. PMMA/sample was lifted from the etching solution and diluted in DI water, and then transferred onto SiO₂/Si substrate. The PMMA layer was removed with acetone and isopropanol. The WSe₂—MoS₂ heterojunction device was made by electron-beam lithography and the contact metal thin film of Pd (30 nm) for WSe₂ and Ti/Au (10/20 nm) was fabricated by electron-beam deposition.

To estimate the depletion width of lateral junction between MoS₂ and WSe₂, the depletion approximation to solve Poisson's equation was used based on the assumptions of no free carriers and constant dopant concentration in the depletion region:

$$\frac{d \text{?}}{dx} = \frac{{qN}_{{MoS}_{2}} {x}_{n}}{\text{?}} = \frac{{qN}_{{WSe}_{2}} {x}_{p}}{\text{?}}$$

$$\text{?} \text{indicates text missing or illegible when filed}$$

The depletion width, W=xₙ+xₚ can be analytically solved as

$$\sqrt{\frac{2 \text{?}}{q} \text{?} ( \frac{1}{{N}_{{MoS}_{2}}} + \frac{1}{{N}_{{WSe}_{2}}} )}$$

$$\text{?} \text{indicates text missing or illegible when filed}$$

where the unintentional doped carrier density in monolayer MoS₂ and WSe₂ have been reported in the order of 10¹⁰ cm⁻², the dielectric constant of MoS₂ and WSe₂ monolayers were comparable [symbol] and εᵣ˜4, and the built-in potential was taken to be about 0.3 eV. Accordingly, the estimated depletion width was about 515 nm, 370 nm, or 92 nm corresponding to (N_{MoS2}, N_{WSe2}) at values of cm⁻² of (10¹⁰, 10¹⁰), (10¹¹, 10¹⁰), or (10¹¹, 10¹¹), respectively, with the referred parameters.

Raman spectra were collected in a Witec alpha 300 confocal Raman microscopic system including RayShield coupler with exciting laser wavelength of 532 nm and the laser spot-size was around 0.5 μm. For the Raman characterizations, the Si peak at 520 cm⁻¹ was used as reference for wavenumber calibration. Emitted Stokes Raman signal was collected by a 100×objective (N.A=0.9) from Carl Zeiss Microscopy GmbH and dispersed by a 1800 lines/mm grating for Raman measurement and a 300 lines/mm grating for PL measurements. PL measurement was also performed in the Witec alpha 300 confocal system.

Surface morphology and surface potential of the samples was examined with commercial multifunction atomic force microscope (Cypher ES—Asylum Research Oxford Instruments). Olympus (OMCL-AC240™) Pt-coated cantilevers were used for this experiment. The tip curvature was about 15 nm, the quality factor was about 190, and the resonance frequency was about 70 kHz.

The STEM imaging was carried out in JEOL-2100F microscope equipped with a cold field emission gun operated at 60 kV and a DELTA corrector. The probe current was 15⁻¹⁰ pA. The ADF images were recorded at a convergence angle of 24 mrad and inner semiangle of 55 mrad. The vacuum level in the TEM chamber is −1.5×10⁻³ pa. The EELS line scan were taken using Gatan low-voltage quantum spectrometer with 0.1 eV dispersion and the spectrum pixel time of 0.5 sec.

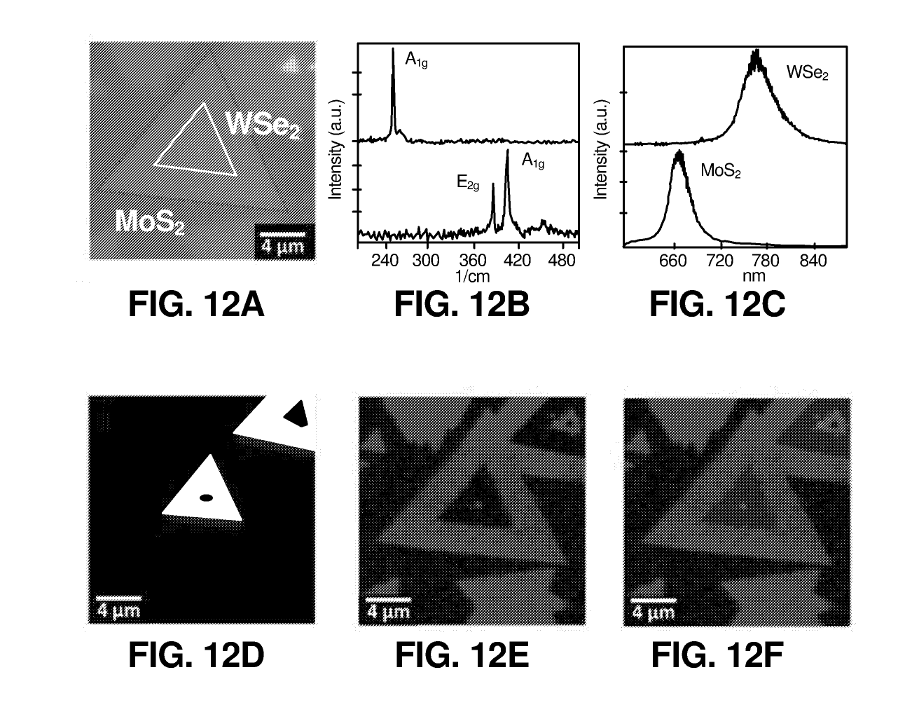

The measurement was carried out in the back-reflection geometry using a pump laser normally incident on the sample. The fundamental pulse laser beam with a central wavelength of 870 nm was obtained from a mode-locked Ti:sapphire laser with a pulse width of 150 fs and a repetition rate of 80 MHz and was linearly polarized along the direction indicated in FIGS. 12a and 12b. The fundamental laser beam with a time-averaged power of 15 mW was tightly focused to a spot size of about 1 μm on the sample surface by a microscope 100× objective lens (N.A=0.9). For spatial mapping of SH intensity, the sample was mounted on a motorized x-y stage with step of 0.25 μm. The SHG with polarizations parallel (IH) and perpendicular (IV) to the laser polarization were separated by a polarization beam splitter, and detected simultaneously by a spectrometer equipped with a nitrogen-cooled CCD camera. The angle θ between the direction of laser polarization and the nearest armchair axis of the sample was calculated by using 0=(⅓)tan⁻¹ √Iᵥ/I_{H}.

The measurement was carried out in a probe-station and measured by Keithley 4200 with a halogen lamp light source (power density E_{w} of 1 mW/cm²) normally incident on sample.

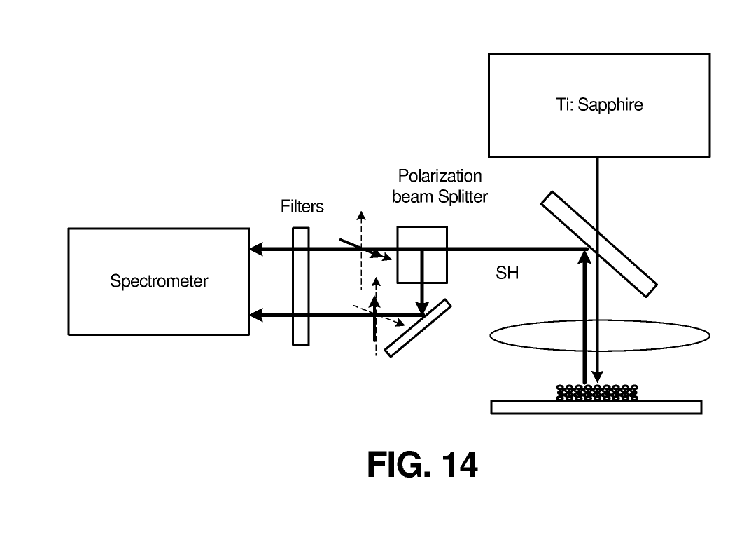

The power conversion efficiency (PCE) calculated by PCE=I_{SC}V_{OC}FF/E_{W}A_{C}, where FF is filling factor and A_{C} is the effective area with energy conversion. The I_{SC} and V_{OC} can be extracted from the I_{V} measurements. The FF is the ratio of maximum obtainable power to the product of the V_{OC} and I_{SC}. The maximum obtainable power was about 6.6×10⁻¹³ W and the FF was 0.39 extracted from the I_{V} measurement under a white light illumination of power density E_{w}=1 mW/cm² in FIG. 14c. For the Ac, the maximum area that can contribute to photon-electron conversion was considered, which is the depletion region of PN junction plus the adjoined diffusion region of TMDC layers. The length of area was entire junction surrounded WSe₂, which was the circumference of the WSe₂˜32 μm estimated form FIG. 14b. The width of A_{C} was the depletion length (340 nm) estimated from Posisson's equation plus the diffusion length of each MoS₂ (400 nm) and WSe₂ (160 nm) based on previous reports, totally ˜1 μm. Therefore the A_{C} area was 32 μm² in total. Based on above information, the PCE was about 0.2%. It was noted that this number is the minimum value based on overestimation of the length of the junction.

The morphology of in-plane heterostructures was examined by optical microscopy (OM) and photoluminescence (PL) and Raman spectroscopies. FIG. 7B shows the OM images of the lateral WSe₂—MoS₂ heterojunctions. All of the WSe₂ triangles were uniformly surrounded by MoS₂, and the domain for WSe₂ and MoS₂ can be distinguished simply by their optical contrast. The lattice constant of WSe₂ was 5.53% larger than MoS₂, which might be one of the factors restricting the growth of MoS₂ onto WSe₂ basal planes. The Raman and PL spectra, in FIG. 12 verified the chemical composition of inner WSe₂ and outer MoS₂ and also revealed the formation of the seamless WSe₂—MoS₂ junction.

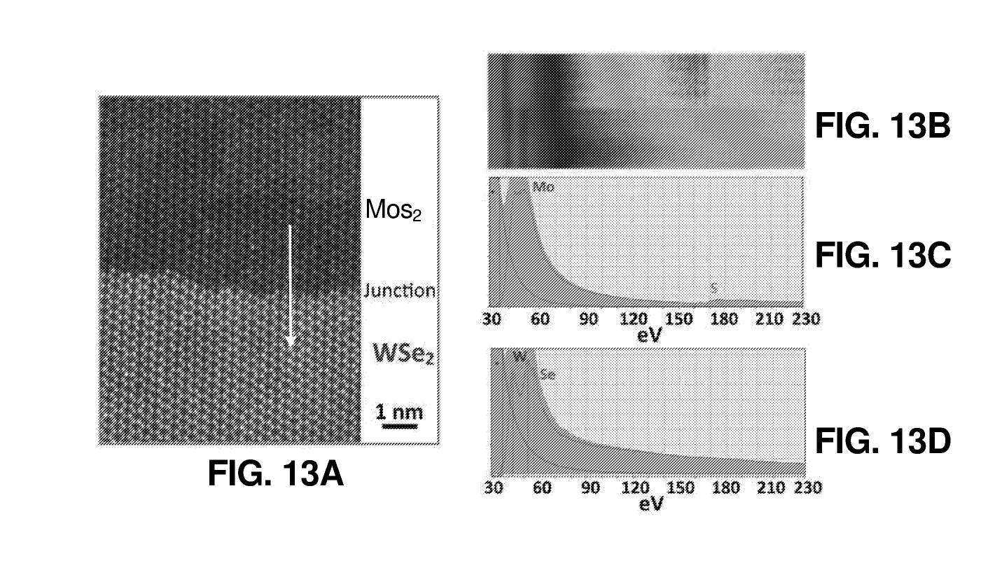

The annular dark field (ADF) image of the lateral WSe₂—MoS₂ junction obtained with scanning transmission electron microscopy (STEM) revealed that the ADF signal increased with the atomic number (Z) as ˜Z^{1.7} (FIG. 7C). Thus, the W, Mo, Se, and S atoms could be distinguished by their intensity. The ADF image for another location (FIG. 7D) shows the atomic models corresponding to the obtained image. An atomically sharp interface between the WSe₂—MoS₂ junction was formed, where about 90% of W atoms were located at the interface bridging to two pair of Se atoms and one pair of S atoms, as depicted in FIG. 7E. In addition to the ADF image, the coherent interface was also identified by the electron energy loss spectroscopy (EELS) measurement. The EELS line scan (by monitoring the EELS spectra change across the hetero-junction) shown in FIG. 13 verified an atomically sharp change. These observations suggested that the growth starts from the replacement of Se atoms of WSe₂ edge by S atoms.

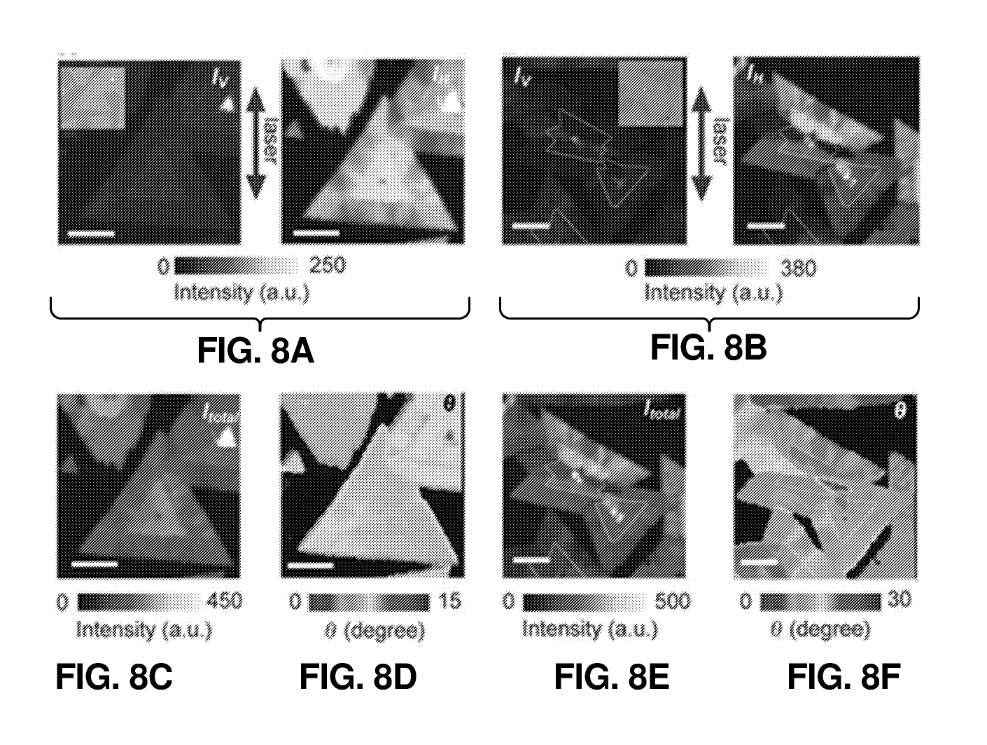

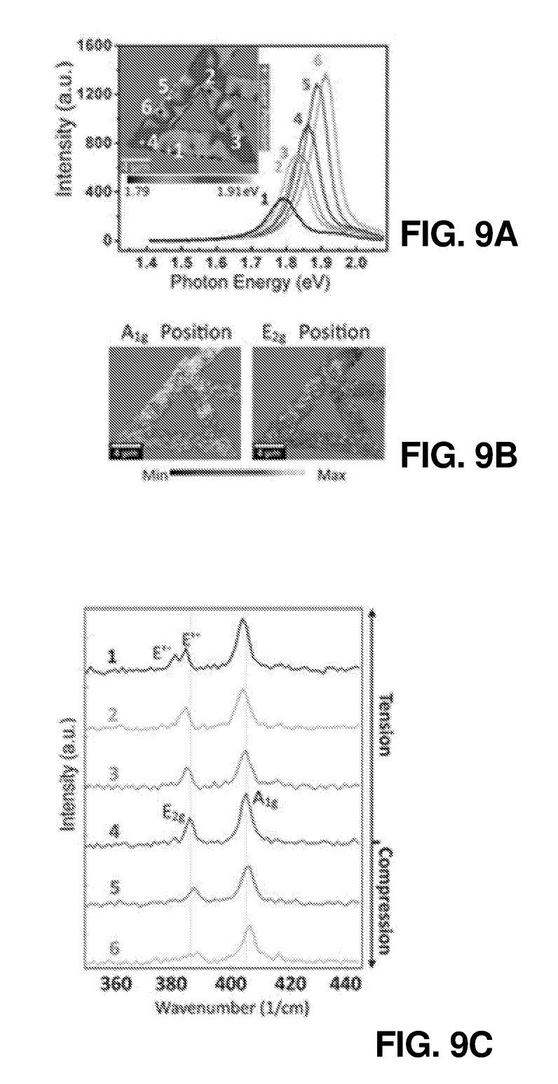

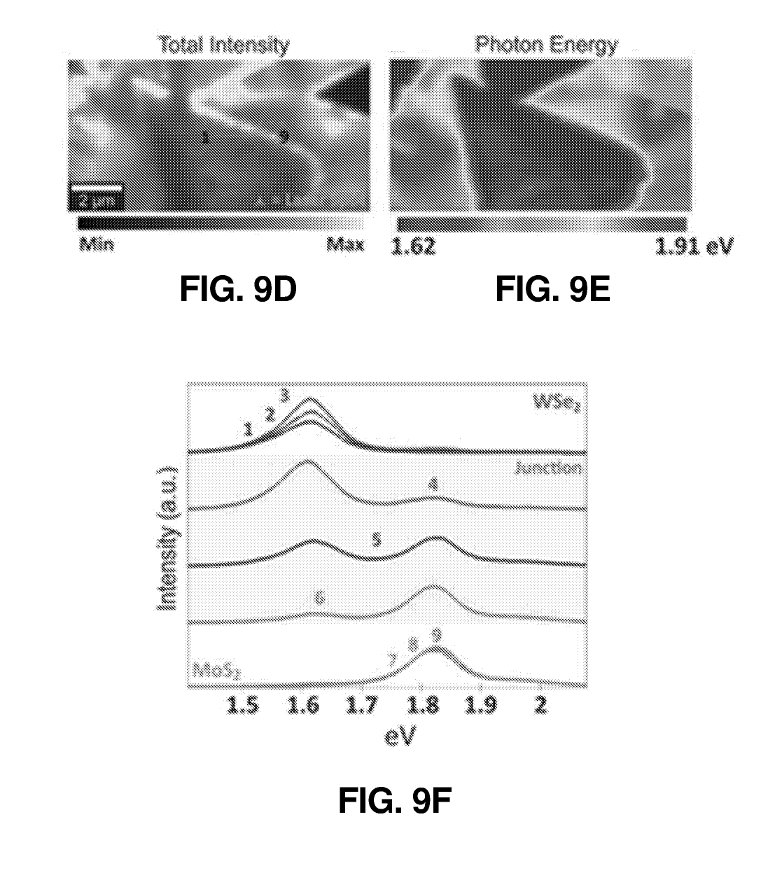

Polarization-resolved second-harmonic generation (SHG) microscopy is sensitive to the crystal orientation and domain boundaries of surface layers. A back-reflection geometry was used with a linearly polarized pump laser (870 nm) normally incident on a triangular WSe₂—MoS₂ heterostructure sample and detected the SHI intensities with polarizations parallel (I_{H}) and perpendicular (I_{V}) to the laser polarization (FIG. 8A) (see FIG. 14 for the setup). As shown in FIG. 14, SHG measurement was carried out in the back-reflection geometry using a pump laser normally incident on the sample, and detecting the SH intensity with polarizations parallel I_{H} and perpendicular I_{V} to the laser polarization. The filter in front of the spectrometer blocks the fundamental laser beam. The total SH intensity Iₜₒₜₐₗ (sum of I_{V} and I_{H}) (FIG. 8C), which was generally uniform over the entire WSe₂ and MoS₂ domains, indicated that the surrounding MoS₂ was also single crystalline without grain boundaries. The SH intensity also showed no suppression across the junction, which suggested that the MoS₂ grew out from the edges of WSe₂ without misorientation. The MoS₂ regions showed slight variations in SHI intensity that coincided well with the variations in PL intensity and peak energy (FIG. 9A, inset). The SH intensity variations in the surrounding MoS₂ arose from the nonuniform strain distribution rather than presence of multiple grains.

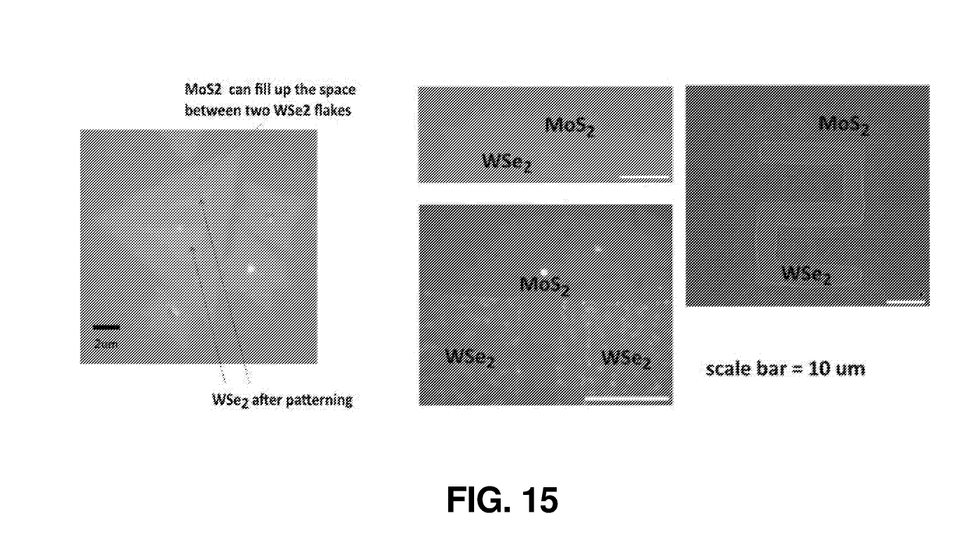

To gain more insight into the WSe₂—MoS₂ heterojunction growth, the crystal orientation was calculated using θ=(⅓) tan⁻¹√Iᵥ/I_{H}, where θ is the angle between the laser polarization direction and the nearest armchair axis of the sample. The map of q (FIG. 8D) was uniform over the entire WSe₂—MoS₂ heterostructure, indicating that the outgrowing MoS₂ was a single crystal with the same orientation as the inner WSe₂. SHI-measurements were also performed on a WSe₂—MoS₂ heterojunction composed of multiple grains (FIGS. 8B and 8E). Although these grains had different orientations (q map, FIG. 8F), the outgrowing MoS₂ followed the orientation of the inner WSe₂. These results indicate that the outgrowth of MoS₂ occurred through epitaxy off the edge of WSe₂ and determined the crystal orientation, rather than the sapphire substrate. FIG. 15 demonstrated that the MoS₂ monolayer also grew out from the prepatterned WSe₂ monolayer. As shown in FIG. 15, WSe₂ film typed monolayer was deposited on sapphire substrates followed by conventional lithographic techniques to form various patterns. Then the second growth of MoS2₂ was performed. MoS₂ monolayers were observed growing from the edge of patterned WSe₂.

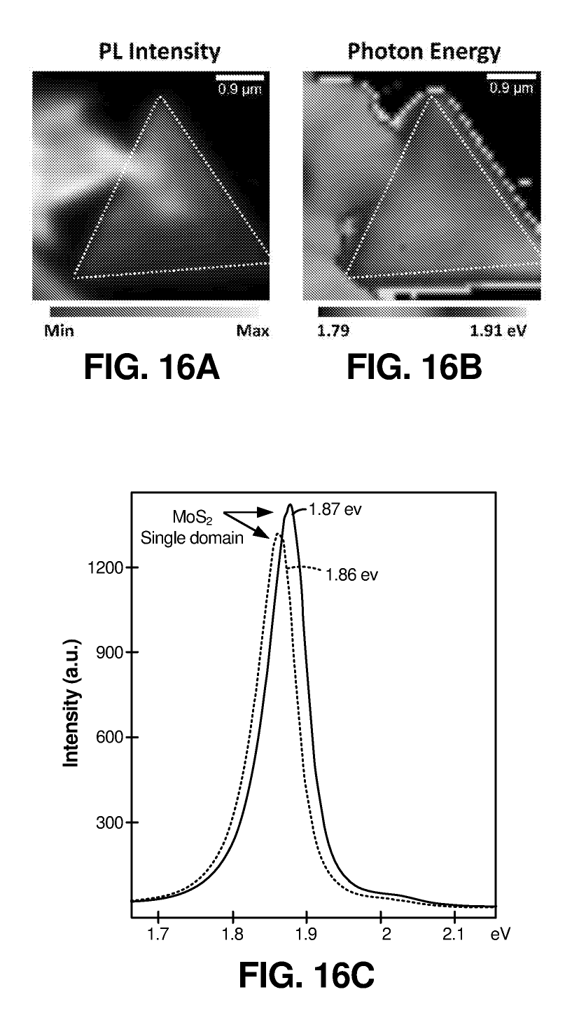

The MoS₂ in WSe₂—MoS₂ heterostructures normally exhibited considerable PL energy differences at different locations (FIG. 9A, inset), where the contour color mapping shows the spatial distribution of PL energy ranging from 1.79 to 1.91 eV. The site with a higher PL energy always exhibited a higher intensity, as presented in the PL spectra (FIG. 9A). However, such a large variation in PL was not observed in isolated MoS₂ monolayers occasionally found on the same sample (FIG. 16), so the MoS₂ PL variation was related to the heterostructure formation. We also performed Raman imaging for the MoS₂ A1g and E₂g frequencies (FIG. 9B). Compared with the inset of FIG. 9A, the location with a higher PL intensity and energy also exhibited higher A_{1g} and E_{2g} frequencies.

Based on the strain dependent E_{2g} and A_{1g} Raman modes in MoS₂ monolayer, both the PL and Raman variations reflect the local strain distribution in the MoS₂. The frequency upshift (downshift) of both Raman modes was associated with a compressive (tensile) strain. The spectra from the isolated MoS₂ and the three corners of the triangular heterostructure have an identical PL energy of 1.86 eV, near that of 1.82±0.02 eV from unstrained MoS₂. For simplicity, assuming the isolated MoS₂ was nearly strain free, the relative strain on MoS₂ could be mapped out; the tensile area was colored with green, cyan, and black, and the compressive area was colored with red and yellow in the inset of FIG. 9A. The representative Raman spectra under tensile and compressive strain (FIG. 9C) showed that the MoS₂ with the lowest PL energy (1.79 eV) was frequently observed from the area with a tensile strain. As the compressive strain increases, the PL peak shifted to a higher energy with a pronounced intensity increase. Symmetry breaking of the crystal broke the degeneracy in the MoS₂ E_{2g} Raman mode (subpeaks E′⁻ and E′⁺) for the as-grown TMDC monolayer (black curve).

The strain variation likely originated from the lattice mismatch between MoS₂ and WSe₂. FIG. 9A shows that the strain of MoS₂, adjacent to WSe₂ was tensile (cyan color) and then gradually changed to strain free (blue color), particularly at the corners. To balance the strain built upon the MoS₂, some MoS₂ areas exhibited compressive strain (red color). We estimated the strain (relative to the as-grown isolated MoS₂) in the MoS₂ region of the MoS₂—WSe₂ heterostructure to be 1.59±0.25% for largest tensile strain and 1.1±0.18% for largest compressive strain, based on the reported linear PL energy shift rate of 45 meV/% strain. Such a large strain difference induced by the lateral heterostructure indicated the possibility of using monolayer TMDCs for straintronices.

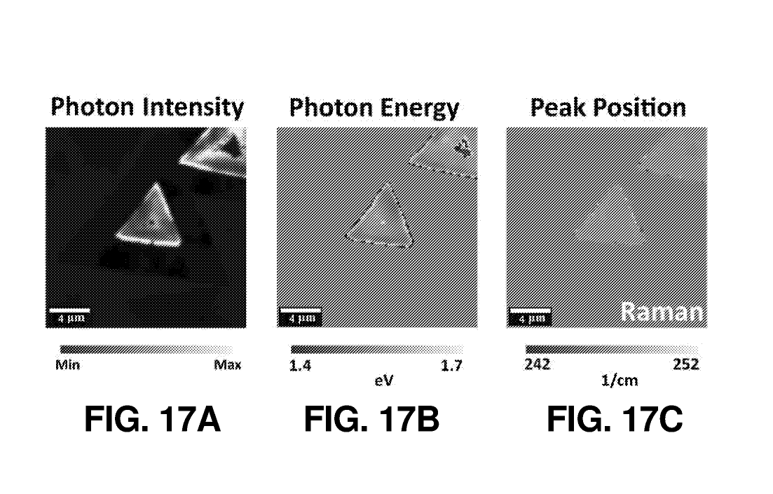

In the inner triangular WSe₂, the PL spectra showed a prominent direct band-gap emission at ˜1.63 eV. By contrast to the outer MoS₂ region, the PL energy and intensity in the WSe₂ region did not show pronounced variations (FIGS. 9D and 9E). Additionally, the Raman frequencies of the WSe₂ region were also relatively unchanged (FIG. 17). Interestingly, FIG. 9D shows that the PL emission from the heterojunction interface was stronger and the PL enhancement was localized at the WSe₂ side of the lateral interface. The PL spectra taken from the points marked as 1 through 9 in FIG. 9D are displayed in FIG. 9F, where two characteristic peaks—1.62 eV for WSe₂ (points 1 to 3) and 1.85 eV for MoS₂ (points 7 to 9)—were observed, respectively. The line scan was performed at a selected MoS₂ area nearly free of strain. Noticeably, the PL spectrum for WSe₂ adjacent to the heterojunction (point 3) showed a narrower and stronger peak at 1.62 eV. The WSe₂—MoS₂ vertical contact formed a type 11 band alignment, with an interband transition peak at ˜1.59 eV. However, no appreciable interband transition in PL measurements was detected.

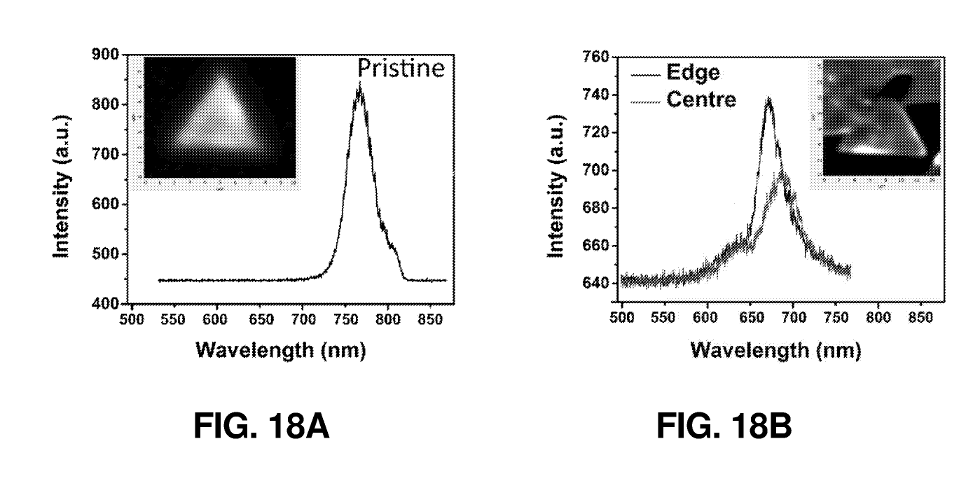

This observation differs from that for the WS₂—MoS₂ heterojunction as previously reported, where a broader PL peak with an intermediate band gap energy, identified as the interband transition, was observed. Meanwhile, it was reported that the edges of WS₂ monolayers exhibited extraordinary PL intensity. STEM results showed that interfacial W was bonded to Se and S, respectively, from each side, and the interface structure was similar to the reported WS₂ edges. A separate study on gas phase sulfurization of isolated WSe₂ monolayer triangles found that the PL emission from WSe₂ edge was largely enhanced after edge sulfurization (FIG. 18). The enhancement of PL at the interface was related to the chemical composition change in the junction.

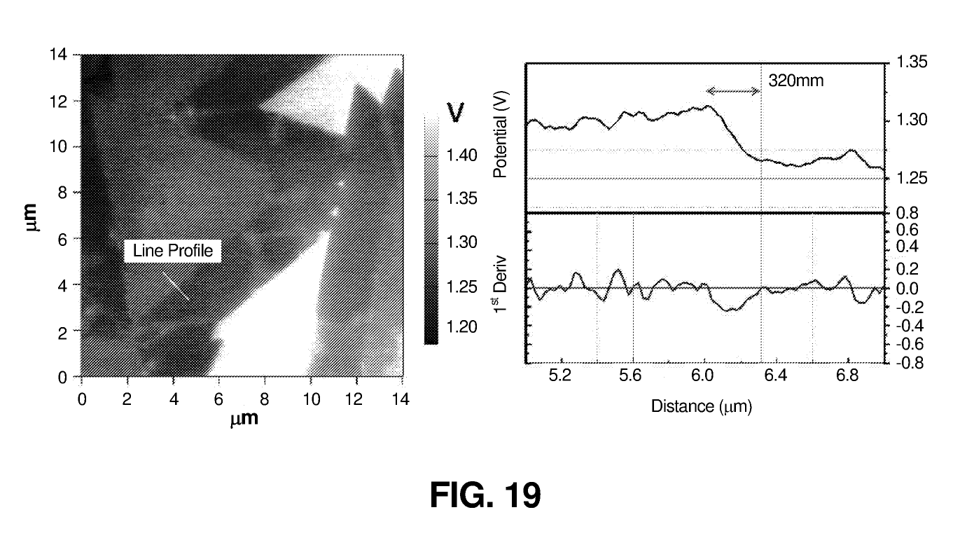

To study the depletion region of the atomically sharp WSe₂—MoS₂ heterojunction, scanning Kelvin probe microscopy (SKPM) was used to directly extract the spatial distribution of the surface potentials. FIG. 4A and its inset show the SKPM and atomic force microscopy (AFM) images for the junction, respectively. The color contrast in the SKPM image between the WSe₂ and MoS₂ regions revealed the distinct potential difference across the junction. SKPM allowed the measurement of depletion width, but the actual built-in potential difference was not accurate because it was strongly affected by the surface adsorbates. The line profile in FIG. 19 revealed that the junction depletion width is ˜320 nm. The value agreed with that of the 100 to 500 nm estimated from the depletion approximation of solving Poisson's equation based on the assumptions of no free carriers and constant dopant concentration in the depletion region.

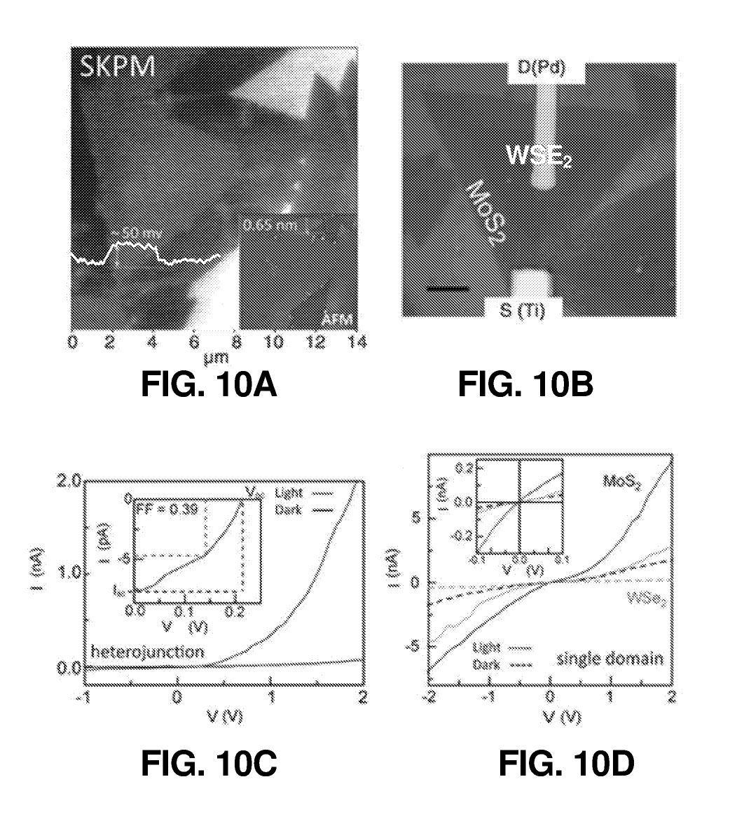

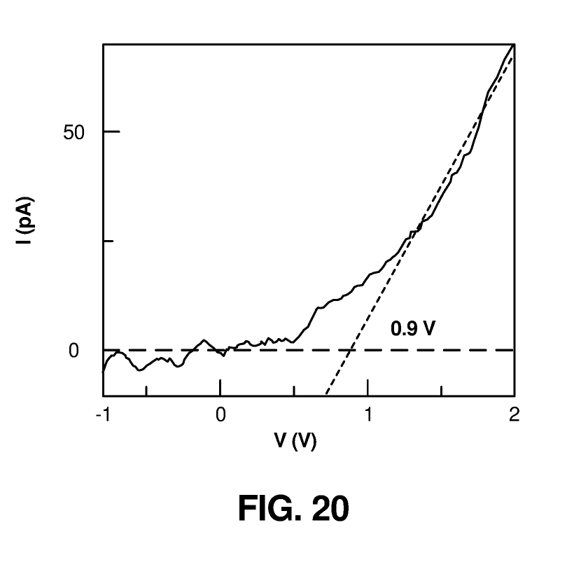

To investigate the electrical properties, the as-grown WSe₂—MoS: heterojunction was transferred onto a SiO₂/Si substrate, and two contact metals, Pd and Ti/Au, were deposited on WSe₂ and MoS₂, respectively. FIG. 10B shows the OM image of the WSe₂—MoS₂ heterojunction, and FIG. 10C shows the current-voltage (I-V) curves of the heterojunction without (black) and with (red) white light illumination. The characteristic curve exhibited good rectification character, with a threshold voltage at about 0.9 V under forward bias (FIG. 20). A photovoltaic effect with an open-circuit voltage J_{c} of 0.22 V and short-circuit current s of 7.7 pA under white light illumination (power density E_{w} of 1 mW/cm²) was shown in the inset of FIG. 10C. The nearly symmetric I-V curves and barely photovoltaic effect for individual WSe₂ (contacted with Pd) and MoS₂ (contacted with Ti/Au) in FIG. 10D corroborated that the p-n junction from the heterostructure was predominant, rather than the small Schottky barriers between metal and TMDCs.

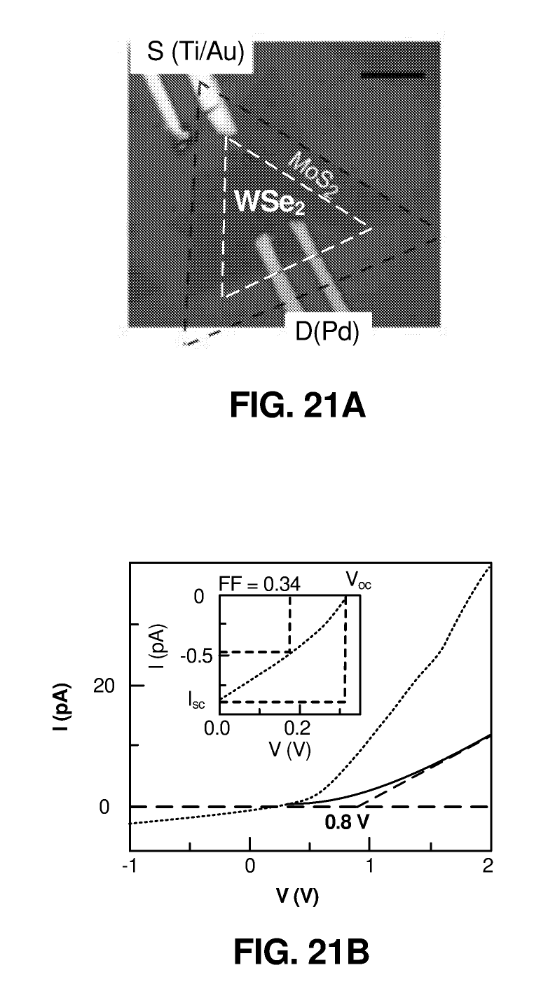

The power conversion efficiency (PCE) of the device was calculated with the photon-to-electron conversion equation, PCE=I_{SC}V_{OC}FF/E_{W}A_{C}, where FF is the fill factor and A_{C} is the effective area with energy conversion. The FF of 0.39 was extracted from the inset of FIG. 10C. The small FI, might result from the high equivalent series resistance of the intrinsic TMDC layers. The maximum A_{C} was estimated by considering both the depletion area of the junction and the adjacent diffusion area of each TMDC layers, giving rise to a maximum area about 32 mm². The calculated PCE was at least 0.2%, comparable with the few-layer MoS₂ vertical p-n junction and monolayer lateral WSe₂ p-n junction. The p-n junction of WSe₂—MoS₂ is further corroborated with the results from another device (FIG. 21), where the carrier transport was clearly through the heterojunction interface. FIG. 21a illustrates an optical image of the selected WSe₂—MoS₂ p-n junction device showing electrical properties of the devices based on heterojunction, according to one or more embodiments of the present disclosure. Part of the film was stripped off during the fabrication processes. This device was uniquely left with a simpler contact structure, where Ti contacts with MoS₂ and Pd with only WSe₂. FIG. 21b illustrates a graphical view of the electrical transport curves (I vs. V) with (red) and without (black) light exposure (1 mW/cm²) showing the presence of a p-n junction and photovoltaic effect, according to one or more embodiments of the present disclosure.

The presence of depletion width (320 nm), rectifying behaviors, photoresponses, and photovoltaic effects confirmed the intrinsic p-n junction properties for lateral WSe₂—MoS₂.

Other embodiments of the present disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form various embodiments. Thus, it is intended that the scope of at least some of the present disclosure should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

The foregoing description of various preferred embodiments of the disclosure have been presented for purposes of illustration and description. It is not intended to be exhaustive or to limit the disclosure to the precise embodiments, and obviously many modifications and variations are possible in light of the above teaching. The example embodiments, as described above, were chosen and described in order to best explain the principles of the disclosure and its practical application to thereby enable others skilled in the art to best utilize the disclosure in various embodiments and with various modifications as are suited to the particular use contemplated. It is intended that the scope of the disclosure be defined by the claims appended hereto

Various examples have been described. These and other examples are within the scope of the following claims.

1. A solar cell, comprising:
a first monolayer and a second monolayer, the first monolayer and the second monolayer forming a monolayer p-n lateral heterojunction with an atomically sharp interface; and
a substrate, the substrate and the monolayer p-n lateral heterojunction forming a solar cell.

2. The solar cell of claim 1, wherein the first monolayer and the second monolayer are characterized by the formula MX₂, wherein M is one or more of molybdenum (Mo) and tungsten (W) and X is one or more of selenium (Se) and sulfur (S).

3-7. (canceled)

8. The solar cell of claim 1, wherein the monolayer p-n lateral heterojunction is an atomically-sharp 2D monolayer WSe₂—MoS₂ p-n lateral heterojunction.

9. The solar cell of claim 1, wherein the first substrate is sapphire.

10. The solar cell of claim 1, wherein the second substrate is a SiO₂/Si substrate.

11. The solar cell of claim 1, further comprising one or more electrodes.

12. (canceled)

13. The solar cell of claim 1, wherein the solar cell is a first solar cell and further comprising a second solar cell, the first solar cell being connected in parallel with the second parallel.

14. The solar cell of claim 1, wherein the solar cell harvests omnidirectional light.

15. The solar cell of claim 1, wherein the solar cell achieves a power conversion efficiency of about 1.78% under AM 1.5G illumination.

16. The solar cell of claim 1, wherein the solar cell achieves a power conversion efficiency of about 1.83% under 1200 W/m² light intensity.

17. The solar cell of claim 1, wherein the solar cell exhibits an environment-independent photovoltaic effect.

18. (canceled)

19. The solar cell of claim 1, wherein the solar cell is used for chemical gas adsorption.

20. A method of making a solar cell, comprising:
growing a first monolayer on a first substrate;
growing a second monolayer on the first substrate sufficient to form a monolayer p-n lateral heterojunction with an atomically sharp interface; and
transferring the monolayer p-n lateral heterojunction from the first substrate to a second substrate sufficient to form a solar cell.

21-22. (canceled)

23. The method of claim 20, wherein growing includes epitaxially growing via chemical vapor deposition.

24-25. (canceled)

26. The method of claim 20, wherein growing the first monolayer and the second monolayer on the first substrate includes one or more of WO₃ powders, Se powders, MoO₃ powders, and S powders.

27. The method of claim 20, wherein growing the first monolayer and the second monolayer on the first substrate includes one or more gases.

28. The method of claim 20, wherein growing the first monolayer and the second monolayer on the first substrate includes reacting in the presence of one or more of argon gas and hydrogen gas.

29. The method of claim 20, wherein growing the first monolayer and the second monolayer on the first substrate includes cooling to about room temperature.

30. The method of claim 20, wherein growing the second monolayer on the first substrate occurs at a lower temperature than the temperature for growing the first monolayer on the first substrate.

31. The method of claim 20, wherein the first monolayer and the second monolayer are characterized by the formula MX₂, wherein M is one or more of molybdenum (Mo) and tungsten (W) and X is one or more of selenium (Se) and sulfur (S).

32-41. (canceled)
